(19) United States
(12) Patent Application Publication
(10) Pub. No.: US 2017/0028622 A1
(43) Pub. Date: Feb. 2, 2017

(54) METHOD AND SYSTEM FOR GENERATING IMAGES AND OBJECTS VIA DISPLAY-AS-PRINT

(71) Applicant: Zadiance LLC, Bozeman, MT (US)

(72) Inventors: Samuel Westlind, Bozeman, MT (US); Daniel O'Loughlin, Billings, MT (US); Frank M. Stewart, Bozeman, MT (US)

(21) Appl. No.: 15/201,210

(22) Filed: Jul. 1, 2016

Related U.S. Application Data
(63) Continuation-in-part of application No. PCT/US2015/058940, filed on Nov. 4, 2015.
Application No. PCT/US2015/058940 is a continuation-in-part of application No. 62/192,809, filed on Jul. 15, 2015.

(51) Int. Cl. B29C 67/00; B33Y 50/02; G03F 7/00; B33Y 10/00

(52) U.S. Cl. CPC B29C 67/0051; B33Y 10/00; B33Y 50/02; G03F 7/0037; B29K 2507/04

(57) ABSTRACT

A method for depositing onto a surface building material that is in powder, slurry or liquid form. The building material is comprised at least in part of a photosensitive material. The method involves exposing the building material to a first specific wavelength of radiation to process the building material to form a first object layer, depositing onto the first object layer additional building material in powder, slurry or liquid form, exposing the additional building material that is deposited onto the first object layer to a second specific wavelength of radiation to process the additional building material to form a second object layer, and repeating the deposition and exposure steps to create as many layers as are necessary to complete the object. A computer-implemented system for generating a two-dimensional image comprising a pixel output device, a camera, a sending program and a receiving program.

### CROSS-REFERENCE TO RELATED APPLICATIONS

This application is a continuation-in-part of International Patent Application No. PCT/US15/58940 filed on Nov. 4, 2015. The latter application claims priority to, and the benefit of, of U.S. Provisional Patent Application No. 62/105,386 filed on Jan. 20, 2015 and of U.S. Provisional Patent Application No. 62/192,809 filed on Jul. 15, 2015. All of the foregoing applications are incorporated herein by reference in their entireties.

### FIELD AND BACKGROUND OF THE INVENTION

The invention relates generally to the fields of data transfer, printing and additive manufacturing, and more particularly, to a method and system for the generation of images and objects using pixels to transfer data and radiation to process building material.

For the period of the nineteenth century, with photography beginning to come on the scene, all photographic images were printed by contact printing. Cameras for that time made “negatives” on coated glass plates or paper. This negative was then placed on top of a paper coated with a light-sensitive emulsion and contact printed using sunlight. The resulting positive print would be the exact size of the original negative. During the early years of photographic history, the only light source available for contact printing was the sun. Since the sun is such an intense light source, use of such a high intensity light required these early processes to be slow reacting or take a relatively long exposure time to render a positive image with a full tonal scale.

There are number of different processes invented for hand coating papers that met these requirements. Just a few processes for this purpose are: Platinotype (using Platinum), Palladiotype (using Palladium metal to render image), Kallitype, Gum Bichromate, Salt Prints, Cyanotype, and the like. These processes produce very beautiful prints that, for the most part, were of a single color or monochromatic. Most people are familiar with the sepia tone of the old platinum/palladium prints or the bright blue color of the Cyanotype print. Toward the end of the 19th century and during the first part of the 20th century, some companies produced machine coated paper that can be purchased and used for a few of these processes. Since these old processes vary greatly in their sensitivity to light, especially light in the ultraviolet range of the spectrum, photographers shorten or lengthen their camera exposures to get a less dense or denser negative that will in turn do a contact print properly with a given process. This provides their method of contrast control. In addition, methods of altering the chemistry of the paper coatings were discovered which also allow for contrast control, so that the process can be adjusted to the density of the negative.

For industry, the direct contact photosensitive cyanotype process became widely used for copy. These original blueprint copies were used on the job site for building construction, manufacturing and other mechanical drawings. This process was largely replaced by the 1930's contact print diazo species copy processes. The diazo species yielded fast copy and a variety of colors. Since then, the cyanotype and diazo technology has become largely relegated to the arts and craft industries.

In some later improvements to the cyanotype process, negatives were created from digital printers and then placed over the coated paper and then exposed to an ultraviolet light source for a certain period of time. For instance, the cyanotype process includes first mixing two chemicals to create a photo sensitive solution or ‘sensitizer’. Secondly, the sensitizer is brushed or soaked onto a cotton-based watercolor paper or other substrate. A negative image on a transparency is then made with a laser/inkjet printer or copy machine and placed over the dried, sensitized paper. The assembly is then exposed to UV light source or sunlight and then it is washed in water to develop the image. Although functional for creating images, this system requires access to a computer and digital printer to create the desired negative image to be transferred as well as an UV source to expose the negative and the chemically coated paper. There is a need therefore for a simplified process for transferring images onto a chemically coated paper or substrate without the need for a printer or complicated and bulky computer set-up.

For the period of the mid-20th century to the early 2000's, the invention of the copier greatly increased productivity but for large format high resolution prints and blueprints, diazo species were the dominant technology utilized to create whiteprints and blueprints. This was a two-part system which required a separate work room for direct contact printers, the copier operators and the added expense of ventilation to mediate the ammonia fumes which was used as the developer. As copier technology continued to improve- and costs continued to drop, the labor intensive diazo blueprints were eventually replaced with dot matrix, inkjet and other systems. Two-D copy technology is well understood today and it now appears that 3D printing is the new frontier of print technology and as it is at the forefront of technological efforts to re-invent the entire manufacturing process as it involves many differing techniques but the end result is a printed object. This process utilizes many different methodologies, but all are slow single point of print 2D X, Y axis printing methodologies that print objects made from a limited menu of photosensitive materials that yield low quality and small but often brittle objects.

All of today's print technologies are defined by several inherent flaws: multiple formats, multiple consumables, drivers, and are a location based service as in the user must go to the printer's location to print. In a modern world that offers a mobile lifestyle, the one item that has not seen any advancement in the art is 2D print. There is a need therefore for a simplified printing process to create a format free, legacy driver free, and one that uses less consumables and provides a printed copy that can be made anywhere and at any time. For 3D printing processes, these slow single point of print systems need a true 3D printer and a means to dramatically speed up the throughput of the printing process and yield a high quality and durable object of any size.

In another area of technology, the state of computer communication had been based on binary, which then progressed to machine read and finally to a human interface, such as a terminal or a smartphone. Connectivity allows individual devices to connect and be a part of the Internet and with the advent of the mass production of high resolution LED, OLED and AMOLED display technology and the start of production for Quantum Dot displays, this now allows true on/off pixel by pixel control of photon emissions. Relatedly, RFID and NFC (near field connectivity) data carriers are being utilized to actively track inventory, assets and to reduce theft, and improve ordering and offer much potential to allow an end user, for example, an enhanced shopping experience whereby the checkout is merely a pass gate that reads the entire shopping cart full of goods eliminating checkout line congestion and adding greatly to the customer's convenience. With such speed in innovation and technology, there is a need throughout our networks for improved secured communication capability while providing ease of portability and use for the consumer while also providing low cost, end to end asset management for the internet of things, the internet of value and the pursuit of ubiquity for end user device controlled commerce.

### SUMMARY OF THE INVENTION

The present invention is a method for creating a two-dimensional image comprising the steps of: providing a substrate with a first layer of microencapsulated material, the microencapsulated material being photosensitive; providing a substrate with a second layer of microencapsulated material, the microencapsulated material being electrically conductive; exposing the first layer of microencapsulated material to a first specific wavelength of radiation in a specific image pattern, thereby releasing the photosensitive material from microencapsulation; exposing the released photosensitive material to a second specific wavelength to process the photosensitive material and bond it to a first surface of the substrate; exposing the second layer of microencapsulated material to a third specific wavelength of radiation in a specific image pattern, thereby releasing the electrically conductive material from microencapsulation; and exposing the released electrically conductive material to a fourth specific wavelength of radiation to process the electrically conductive material and bond it to a second surface of the substrate.

In an alternate embodiment, the present invention is a method for creating a two-dimensional image comprising the steps of: providing a substrate with a layer of microencapsulated material, the microencapsulated material being photosensitive; exposing the layer microencapsulated material to a first specific wavelength of radiation in a specific image pattern, thereby releasing the photosensitive material from microencapsulation; and exposing the released photosensitive material to a second specific wavelength to process the photosensitive materials and bond it to a surface of the substrate.

In an alternate embodiment, the present invention is a method for depositing electrically conductive materials onto a substrate comprising the steps of: providing a substrate with a layer of microencapsulated material, the microencapsulated material being at least partially photosensitive and at least partially electrically conductive; exposing the layer of microencapsulated material to a first specific wavelength of radiation in a specific pattern, thereby releasing the electrically conductive material from microencapsulation; and exposing the released electrically conductive material to a second specific wavelength of radiation to process the electrically conductive material and bond it to a surface of the substrate.

In an alternate embodiment, the present invention is a method for generating an electrically conductive three-dimensional object comprising the steps of: depositing onto a surface a microencapsulated material that is at least partially comprised of photosensitive material and at least partially comprised of electrically conductive material in powder, slurry or liquid form; exposing the microencapsulated material to a first specific wavelength of radiation, thereby releasing the electrically conductive material from microencapsulation; exposing the released electrically conductive material to a second specific wavelength of radiation to process the electrically conductive material to form a first object layer; depositing onto the first object layer a microencapsulated material that is at least partially comprised of photosensitive material and at least partially comprised of electrically conductive material in powder, slurry or liquid form; exposing the microencapsulated material that is deposited onto the first object layer to a third specific wavelength of radiation, thereby releasing the microencapsulated electrically conductive material from microencapsulation; exposing the released electrically conductive material that is deposited onto the first object layer to a fourth specific wavelength of radiation to process the electrically conductive material to form a second object layer; and repeating the deposition and exposure steps to create as many layers as are necessary to complete the object.

In an alternate embodiment, the present invention is a method for generating an electrically conductive three-dimensional object comprising the steps of: depositing onto a surface a microencapsulated material that is comprised at least partially of photosensitive material and at least partially of electrically conductive material in powder, slurry or liquid form; exposing the microencapsulated material to a first specific wavelength of radiation, thereby releasing the electrically conductive material from microencapsulation; exposing the released electrically conductive material to a second specific wavelength of radiation to process the electrically conductive material and bond it to the surface to form a first additive layer; depositing onto the first additive layer a microencapsulated material that is comprised at least partially of photosensitive material and at least partially of electrically conductive material in powder, slurry or liquid form; exposing the microencapsulated material that is deposited onto the first additive layer to a third specific wavelength of radiation, thereby releasing the microencapsulated electrically conductive material from microencapsulation; exposing the released electrically conductive material that is deposited onto the first additive layer to a fourth specific wavelength of radiation to process the electrically conductive material to form a second additive layer; and repeating the deposition and exposure steps to create as many layers as are necessary to complete the object.

In an alternate embodiment, the present invention is a method for generating a three-dimensional object comprising the steps of: depositing onto a surface a microencapsulated material that is comprised at least partially of photosensitive material and at least partially of building material in powder, slurry or liquid form; exposing the microencapsulated material to a first specific wavelength of radiation, thereby releasing the building material from microencapsulation; exposing the released building material to a second specific wavelength of radiation to process the building material to form a first object layer; depositing onto the first object layer a microencapsulated material that is comprised at least partially of photosensitive material and at least partially of building material in powder, slurry or liquid form; exposing the microencapsulated material that is deposited onto the first object layer to a third specific wavelength of radiation, thereby releasing the microencapsulated building material from microencapsulation; exposing the released building material that is deposited onto the first object layer to a fourth specific wavelength of radiation to process the building material to form a second object layer; and repeating the deposition and exposure steps to create as many layers as are necessary to complete the object.

In an alternate embodiment, the present invention is a method for generating a three-dimensional object comprising the steps of: depositing onto a surface a microencapsulated material that is comprised at last partially of photosensitive material and at least partially of building material in powder, slurry or liquid form; exposing the microencapsulated material to a first specific wavelength of radiation, thereby releasing the building material from microencapsulation; exposing the released building material to a second specific wavelength of radiation to process the building material and bond it to the surface to form a first additive layer; depositing onto the first additive layer a microencapsulated material that is comprised at least partially of photosensitive material and at least partially of building material in powder, slurry or liquid form; exposing the microencapsulated material that is deposited onto the first additive layer to a third specific wavelength of radiation, thereby releasing the microencapsulated building material from microencapsulation; exposing the released building material that is deposited onto the first additive layer to a fourth specific wavelength of radiation to process the building material to form a second additive layer; and repeating the deposition and exposure steps to create as many layers as are necessary to complete the object.

Preferably, the step of exposing the microencapsulated material to a specific wavelength is implemented via at least one display device that is in direct contact with the microencapsulated material, and the step of exposing the released material to a specific wavelength is implemented via at least one display device that is in direct contact with the released material. The at least one display device is preferably moveable. Preferably, the step of exposing the microencapsulated material to a specific wavelength is implemented via at least one display device that is in direct contact with the microencapsulated material, and the step of exposing the released material to a specific wavelength is implemented via at least one display device that is in direct contact with the released material, and the at least one display device is configured to move away from the object as it increases in size.

Preferably, the step of exposing the microencapsulated material to a specific wavelength and the step of exposing the released material to a specific wavelength are implemented by more than one display device, and the more than one display devices are configured to form a manufacturing chamber within which the object is generated. Preferably, each of the more than one display devices has a display surface that is load-bearing and configured to provide a surface against which the object rests as it is being generated.

In an alternate embodiment, the step of exposing the microencapsulated material to a specific wavelength is implemented via at least one catheter that is in direct contact with the microencapsulated material, and the step of exposing the released material to a specific wavelength is implemented via at least one catheter that is in direct contact with the released material. The at least one catheter is preferably moveable. Preferably, the step of exposing the microencapsulated material to a specific wavelength is implemented via at least one catheter that is in direct contact with the microencapsulated material, and the step of exposing the released material to a specific wavelength is implemented via at least one catheter that is in direct contact with the released material, and the at least one catheter is configured to move away from the object as it increases in size.

The present invention is also a method for generating a three-dimensional object comprising the steps of: depositing onto a surface building material that is in powder, slurry or liquid form, wherein the building material is comprised at least in part of a photosensitive material; exposing the building material to a first specific wavelength of radiation to process the building material to form a first object layer; depositing onto the first object layer additional building material in powder, slurry or liquid form, wherein the building material is comprised at least in part of a photosensitive material; exposing the additional building material that is deposited onto the first object layer to a second specific wavelength of radiation to process the additional building material to form a second object layer; and repeating the deposition and exposure steps to create as many layers as are necessary to complete the object.

The present invention is also a method for generating a three-dimensional object comprising the steps of: depositing onto a surface building material in powder, slurry or liquid form, wherein the building material is comprised at least in part of a photosensitive material; exposing the building material to a first specific wavelength of radiation to process the building material and bond it to the surface to form a first additive layer; depositing onto the first additive layer additional building material in powder, slurry or liquid form, wherein the building material is comprised at least in part of a photosensitive material; exposing the additional building material that is deposited onto the first additive layer to a second specific wavelength of radiation to process the additional building material to form a second additive layer; and repeating the deposition and exposure steps to create as many layers as are necessary to complete the object.

The present invention is also a method for generating a three-dimensional object comprising the steps of: providing building material that is in powder, slurry or liquid form, wherein the building material is comprised at least in part of a photosensitive material; exposing a first portion of the building material to a first specific wavelength of radiation to process the first portion of the building material to form a first object layer; exposing a second portion of the building material to a second specific wavelength of radiation to process the building material to form a second object layer; and repeating the exposure steps to create as many layers as are necessary to complete the object.

Preferably, the step of exposing the building material to a specific wavelength is implemented via at least one display device that is in direct contact with the building material, and the step of exposing the additional building material to a specific wavelength is implemented via at least one display device that is in direct contact with the additional building material. The at least one display device is preferably moveable. Preferably, the step of exposing the building material to a specific wavelength is implemented via at least one display device that is in direct contact with the building material, and the step of exposing the additional building material to a specific wavelength is implemented via at least one display device that is in direct contact with the additional building material, and the at least one display device is configured to move away from the object as it increases in size.

Preferably, the step of exposing the building material to a specific wavelength and the step of exposing the additional building material to a specific wavelength are implemented via more than one display device that is in direct contact with the additional building material, and the more than one display devices are configured to form a manufacturing chamber within which the object is generated. Preferably, each of the more than one display devices has a display surface that is load-bearing and configured to provide a surface against which the object rests as it is being generated.

In an alternate embodiment, the step of exposing the building material to a specific wavelength is implemented via at least one catheter that is in direct contact with the building material, and the step of exposing the additional building material to a specific wavelength is implemented via at least one catheter that is in direct contact with the additional building material. The at least one catheter is preferably moveable. Preferably, the step of exposing the building material to a specific wavelength is implemented via at least one catheter that is in direct contact with the building material, and the step of exposing the additional building material to a specific wavelength is implemented via at least one catheter that is in direct contact with the additional building material, and the at least one catheter is configured to move away from the object as it increases in size.

In a preferred embodiment, at least one of the exposure steps involves radiation in the range of 10 nanometers to one meter. In yet another preferred embodiment, at least one of the exposure steps is performed by a laser. In yet another preferred embodiment, the radiation is controllable on a pixel-by-pixel level.

The present invention is a computer-implemented system for generating a two-dimensional image, the system comprising: at least one pixel output device; a camera inputting to a computer on which is running a receiving program; a sending program that is displayed on the at least one pixel output device and at which the camera is pointed; wherein when a file is selected from the sending program, the sending program reads the file into bytes, parses the bytes into bits, and saves the bits to a first bit list; wherein the sending program displays a plurality of shapes in a checkerboard pattern, each shape comprising one or more pixels, the checkerboard pattern being determined by the first bit list, and the number of pixels that comprise a shape being defined by pre-coded parameters; wherein the camera sends a video stream of the checkerboard pattern to the computer that is running the receiving program; wherein the camera is any image sensor or image capturing device; and wherein the receiving program analyzes pixels in the frames from the incoming video stream for luminance and color, converts the pixels into a bit list, converts the bit list into a byte list, and writes the byte list to a file.

The present invention is also a computer-implemented method for generating a two-dimensional image comprising the steps of: selecting a file and using a sending program to read the file into a first set of bytes and to convert the first set of bytes into a first set of bits; displaying on a display one or more pixels as determined by the first set of bits; using an image sensor or image capturing device to create a video stream of the image that is displayed on the display; capturing the video stream with the receiving program; and using the receiving program to convert pixels in the video stream into a second set of bits, to convert the second set of bits into a second set of bytes, and to write the second set of bytes to a file.

### BRIEF DESCRIPTION OF THE DRAWINGS

FIG. 1 is a flowchart of an example embodiment of a method or process of transferring an image onto a substrate according to the teachings of the invention; and

FIG. 2 illustrates an example embodiment of a system for transferring an image from a light source onto a substrate according to the teachings of the invention; and

FIG. 3 illustrates an example embodiment of a method to prepare a package for shipment with a shipping service according to the teachings of the invention; and

FIG. 4 illustrates an example embodiment of a method to select and configure an image for optical transfer or physical transfer to a substrate according to the teachings of the invention; and

FIG. 5 is a flowchart of another example embodiment of a method and system to prepare a package for shipment with a commercial shipping service using RFID tracking according to the teachings of the invention; and

FIGS. 6-8 illustrates an example embodiment of a system for using a smart device address a package for shipping, purchasing postage and linking a QR code with an RFID tag on the package according to the teachings of the invention; and

FIGS. 9A and 9B illustrate an example embodiment of a method and a system for sending a selected image or data set via pixel by pixel optical transfer from one smart device to another according to the teachings of the invention; and

FIG. 10 illustrates an example embodiment of a method of performing 3-D printing using an ultraviolet wavelength (UVW) display for pixel by pixel control and image projection according to the teachings of the invention; and

FIG. 11 is a flowchart that illustrates the multiple steps involved in the 2D printing and 3D additive manufacturing processes of a single-plane, single-display application of the present invention; and

FIG. 12 is a flowchart that illustrates the multiple steps involved in the additive manufacturing process of a multi-plane, multiple-display application of the present invention; and

FIG. 13 is an isometric view of the displays comprising a first example application of the present invention, which is a parallelepiped-shaped printer having one display per side, shown with the internal chamber in a minimal volume position; and

FIG. 14 is across-section view of the first example application shown in FIG. 13; and

FIG. 15 is an isometric view of the first example application, shown with the internal chamber in a maximal volume position; and

FIG. 16 is a cross-section view of the first example application shown in FIG. 15; and

FIG. 17 is an isometric view of the second example application of the present invention, which is a parallelepiped-shaped printer having one display per side for the top and bottom, and having four displays per side for the front, rear, left and right sides, shown with the internal chamber in a minimal volume position; and

FIG. 18 is a cross-section view of the second example application shown in FIG. 17; and

FIG. 19 is an isometric view of the second example application, shown with the internal chamber in a maximal volume position; and

FIG. 20 is an isometric view of the third example application of the present invention, which is a parallelepiped-shaped printer having four displays for each of its six sides, shown with the internal chamber in a minimal volume position; and

FIG. 21 is a cross-section view of the third example application shown in FIG. 20; and

FIG. 22 is an isometric view of the third example application, shown with the internal chamber in a maximal volume position; and

FIG. 23 is a perspective view of the fourth example application of the present invention, which is a spherically shaped printer having four concentric layers of adjustable displays when the internal chamber is in the minimal volume position, shown with the internal chamber in a minimal volume position; and

FIG. 24 is a cross-section view of the fourth example application shown in FIG. 23; and

FIG. 25 is a cross-section view of the fourth example application, shown with the internal chamber in a maximal volume position; and

FIG. 26 is a cross-section view of the fifth example application of the present invention, which is a printer comprising a hemispherical top section and a flat bottom section, shown with the internal chamber in a minimal volume position; and

FIG. 27 is a cross-section view of the fifth example application, shown with the internal chamber in a maximal volume position; and

FIG. 28 is a magnified cross-section view of the extrusion ends of two delivery tubes showing the catheters within the delivery tubes; and

FIG. 29 is a flow diagram of one embodiment of the software program that controls the 2D image generation process of the present invention; and

FIG. 30 is an illustration of the bounding box described in connection with step 29f; and

FIG. 31 is an illustration of the checkerboard display pattern described in connection with step 29j.

FIG. 32 shows the image referenced on page 29 herein.

FIG. 33 shows the image referenced on page 30 herein.

### DETAILED DESCRIPTION OF THE INVENTION

Following are more detailed descriptions of various related concepts related to, and embodiments of, methods and apparatus according to the present disclosure. It should be appreciated that various aspects of the subject matter introduced above and discussed in greater detail below may be implemented in any of numerous ways, as the subject matter is not limited to any particular manner of implementation.

Examples of specific implementations and applications are provided primarily for illustrative purposes.

The various embodiments of the invention are directed to transferring from a light source such as smart devices, smartphones or tablets, TVs or SWD printers or forming images on substrates such as paper using such devices, without the use of a separate negative and/or without the use of separate ultraviolet light sources for exposure.

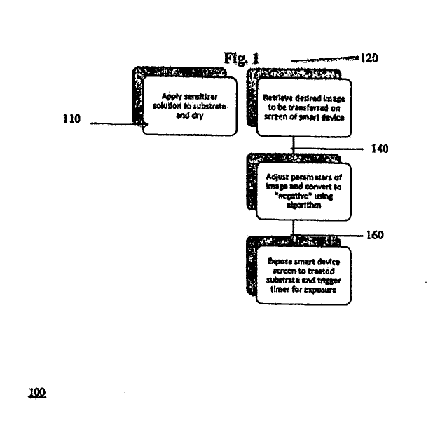

Referring to the figures, FIG. 1 illustrates a flowchart of an example embodiment of a method or process 100 of transferring an image onto a desired substrate, such as a paper or envelope. The method for formulating a cyanotype or diazo-type (with associated microencapsulated developer and stabilizer) sensitizer solution will be described later herein as the composition of the solution will vary depending on various factors including, but not limited to, the substrate used and the type of smart device display used (and exposure settings). In view of the foregoing, prior to step 110, the sensitizer solution is prepared and then in step 110 the sensitizer solution is applied by the user to the desired substrate and dried (either air dried or with a drying tool such as a fan or hair dryer). In step 120, the user then retrieves or selects the desired image on the smart device to be transferred or “printed” onto the substrate. In one example, the QR generated image is a postage stamp for placement on an envelope before mailing. In step 140, the parameters of an image are adjusted on the display of the smart device using an algorithm or applet already uploaded on the smart device. Once the user has selected the image, the applet then converts or “reverses” the image to a “print” and adjusts the exposure parameters to ready the smart device for exposure. In a related embodiment, once the user has selected the appropriate image, the user indicates the type of substrate to be used and any other factors relating to exposure (brightness, resolution, hue, contrast, etc.) and the chemical sensitizer used on the substrate.

In step 160 the smart device is then placed on the coated substrate with the screen facing the coated surface so as to “expose” the sensitizer to the UV or photons emitted by the display. The exposure applet also includes a timer and “beep or chime” (or other alert mechanism, such as a vibration) scheme to assist the user in “timing” the exposure of the image on the coated substrate. Depending on the sensitizer solution used, a developing step, such as water or other developing fluid rinse, may be needed to further develop and “set” the transferred image.

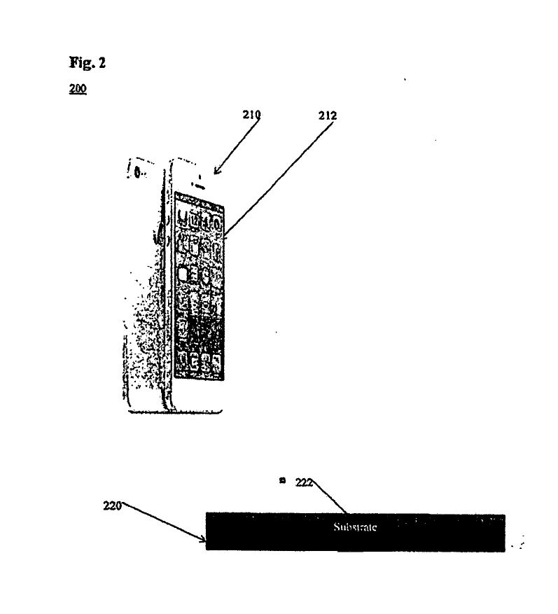

Referring now to FIG. 2, there is illustrated a system 200 for transferring an image from a smart device to a substrate. In this example embodiment, system 200 includes a smartphone 210 with a display 212 that is used to retrieve an image desired for transfer or “printing” and an applet for configuring the image for transfer when the substrate is ready. Once the image (or images) is displayed on display 212, such as a text, puzzle, receipt, tickets, documents, snapchat, a postage stamp or a collection of images such as postage stamp, a sender's address and a receiver's address (what would be on the face of an envelope), display 212 is then placed face down on a substrate 220, specifically on its surface 222 that is coated with a sensitizer solution (or the surface of which has been reconfigured to accept image being transferred).

Another example of a “printable” image would be a shipping label with all of the pertinent information. Display 212 includes various examples of display technology emitting photons for sensitizer exposure such as, but not limited to, LED, OLED (organic LED), AMOLED, Quantum Dot and other similar displays. In another example embodiment, the teachings herein provide for replacing the internal mechanism of existing printers with for example: OLED Display and UVAOLED Display and then use proprietary sensitized paper that is configured as taught herein, thereby eliminating the need for expensive inks or toners to print on the paper. In an example embodiment, image transfer exposure time for current smartphones such as a Samsung Galaxy 6 is currently about 10 minutes for diazo with additional reagents such as AIBN. With a different substrate type, OEM display brightness improvements, control of LED brightness levels, and a smartphone or flat panel TV-type device that is configured to provide UV and that includes a UV control (increase/decrease UV) algorithm and feature, or by using chemical accelerators and/or decreasing the thickness of the finished layer, the process time can be greatly reduced. For cyanotypes, current smart devices do not emit enough lumens to react. However with an LED light pad that emits 900 lumens, the exposure time is about 15 minutes to react the cyano chemistry. To improve fixing the image on the substrate possibly use H20 for cyanotypes to fix the image or use a wetting agent imbedded in paper or plastic protector in place on envelopes. Consider removing before or after image. Or simply dab with water, or other fluid that is convenient. Display or projector system for casting image: max bright=faster image transfer. Faster chemical process may include a fixing agent such as water, lemon juice, vinegar or the like. In this example embodiment, the SWD printer makes both diazo and cyano chemistries react instantly.

An example of the sensitizer coating solution is described herein however which is one embodiment of the “ink cartridge-free printer” system would include a portable container, like a glue pen or cartridge for coating the substrate to be used (such as an envelope) just prior to image transfer. The glue cartridge would have a sponge-like surface to facilitate flow of sensitizer solution as well as for spreading the sensitizer evenly over the substrate. Another example would be a portable 8.5 inch by 11 inch UVWD printer that would look similar to a large tablet. This device emits purple UV rays and a user would have the only consumable necessary for print: the sensitized paper. Upon exposure, Purple burns off diazo and black means diazo stays. In the next step, releasing the encapsulated developer fixes the image.

### Diazo-Compound Based Species Image Generation and Smart Device Image Transfer

In an example embodiment, an applet or software app is disclosed for preparing and transferring an image from a smart device to a substrate. The teachings herein also provide for instant printing using pixels (or in some embodiments LEDs) from smart devices. Thus current commercial LED UV printing via UV ink curing involves the polymerization of inks, adhesives, or lacquers, which are composed of photosensitive compounds, and is generally performed at 395 nm, 385 nm or 365 nm, wavelengths which are part of the UV-A spectrum. Ultraviolet radiation emitted from the diodes excites electrons to their outer orbitals, allowing for a radical-mediated reaction that leads to aliphatic bonds between molecules. Once these bonds are formed, the substrate and/or coating is considered cured and typically converted from a liquid to a solid. The use of the UVWD display as a printer (UVWD printer) with photopolymers allows direct wet bath 3D printing directly from the UVWD device. The entire surface area of the display is the printing surface. An entire schematic can play in a movie format and print a 3D object one entire layer at a time as each movie frame exhibits a slice or layer of the file. In another example embodiment for 2D printing, inks, pigments, or dyes form part of the paper and/or substrate, thereby providing for black, white or color images.

In yet another related embodiment, a business method is provided for using Display as Print technology or image transfer process and system as part of an online or digital post office system, including but not limited to the following modules: a Print module, a Scale module and a Digital Stamps module. These apps would be included as part of the business platform within the Zadiance™ eDigital Post Office. In a related embodiment, such a system is integrated into the USPS (US Postal Service) or other parcel carriers such as Fed Ex, UPS and DHL. In one embodiment, the complete Zadiance™ Post Office is entirely on a smart device capable of in step 1—addressing an envelope by bringing up a Digital Post Office software applet that selects an addressor and addressee from the user's contact list. In step 2, prompting the user to lay the smartphone or smart device display on the envelope or a label for image transfer. In step 3, the user “clicks” or triggers the timer so as to be hands-free; a BEEP (or chime or other alert such as a vibration) means the address is set or has been transferred and/or both the address and addressee. In this example embodiment, the Applet will put on a standard USPS bar code for addressee information. From the postal app, either a buy as you go or a user account money deposited for postage credit is deducted as a QR code representing a postage stamp as it is printed onto envelope for a postage machine to read. Once the addressee (or any other combination of image selected by user) is set, the Applet then prompts the user whether the particular application or use is for a “standard” letter. If so (or “yes”), then a postage stamp is printed. An alert (click, chime or beep, etc.) will occur when the stamp is placed or being placed and when this step is completed.

If the letter or package to be shipped needs to be weighed for proper metering, then the smartphone (or smart device) is placed face up and the MAILSCALE function is selected. For example, an external wired (or wireless) transducer, Wheatstone bridge with strain gauge replacing a resistor, or a piezoelectric device is coupled to the smart device that works as a weight scale that translates a pressure or weight of the package into an actual weight (ounces or grams) that is displayed on the smart device screen or an external third party commercially available scale can be incorporated into the system. The MAILSCALE function then alerts the user that the weight has been calculated using proprietary algorithms and the external or existing smart device components will automatically calculate postage due. An alert advises user that the postage has been calculated based on weight and then the smart device display is placed face down on the envelope or label to “Digitally Stamp” the envelope or package. Other functions can also be selected from the Applet such as buying DIGITAL STAMPS or any other service offered by the Post Office, including sending Priority Mail, etc., all from within the Zadiance™ app on the user's device (or a user account on the US Postal Service website).

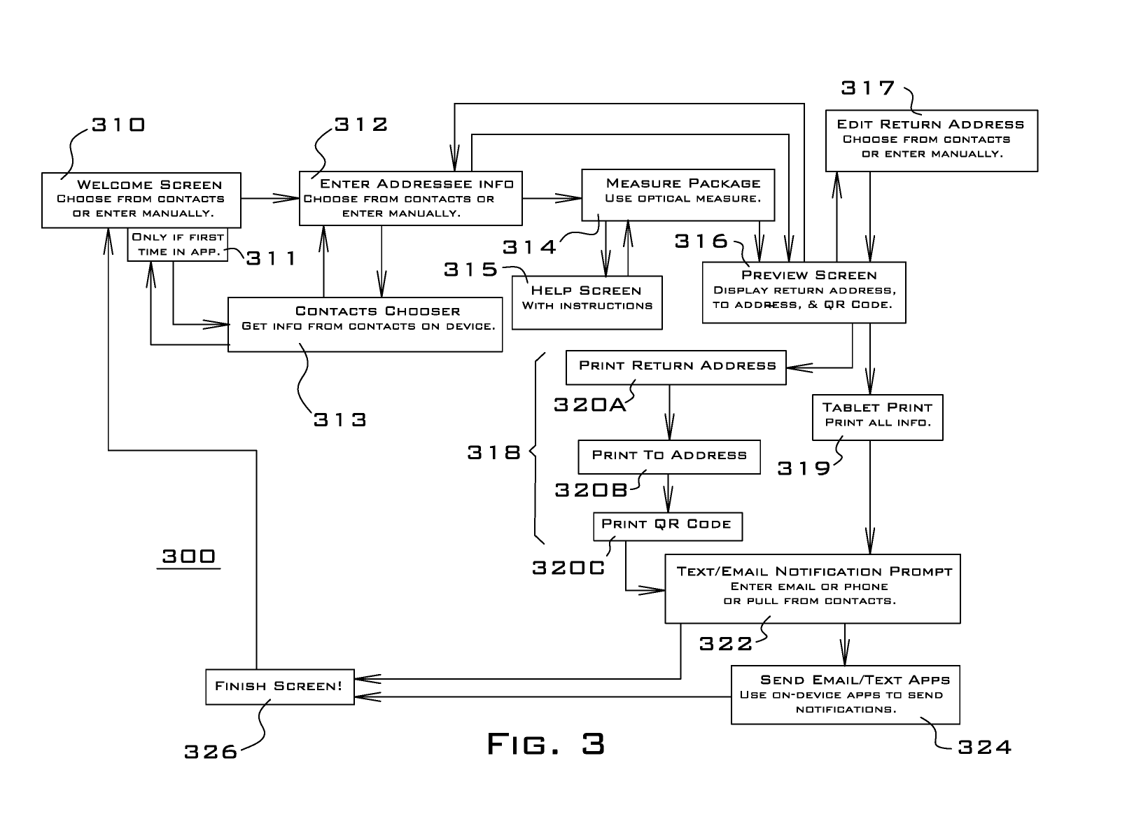

Referring now to FIG. 3, there is illustrated another example embodiment of a method 300 to prepare a package for shipment with a shipping service using a smart device equipped with a software application (or Applet or APP) and image transfer capabilities according to the teachings of the invention. User first opens App to at 310 an views the Welcome Screen in order to choose from the contact list or can enter a name or business manually using the smart device keyboard (or verbally). At 312, the user enters the address information (or can enter this manually as well). At 313 the user selects the Contact selector which allows the information to be obtained from the device itself. For first time users, at 311 there is an interim communication step between the welcome screen 310 and 313 contact selector as the user gets more comfortable with the program. The several lines in the flowchart indicate that the user may also be toggling back and forth between screens of program 300. At 314, the user measures the weight and size of the package to be sent and may access additional support at 315 in this process. At 316, the user previews the “To” and “From” addresses and adds optionally adds a QR code (and/or associates the QR code to the shipping information). If the user needs to edit the Return or To address, at 317 the user can step back and take care of this. At 318, the user has at least two options for printing, either using a tablet printer 319 or another smart device 320 that may require more “printing” steps for placing the shipping information on a label or directly on the package to be shipped. At 320a the Return address is printed; at 320b the To address is printed; and at 320c the QR is printed. After the print sequence 318, an email or text notification/prompt appears at 322 in order for the user to manually enter this information or to pull this information from the smart device contact information. After 322, the user can either move to the Finish screen 326 or access an interim step of 324 of sending an email or using a text App on the smart device to send notifications.

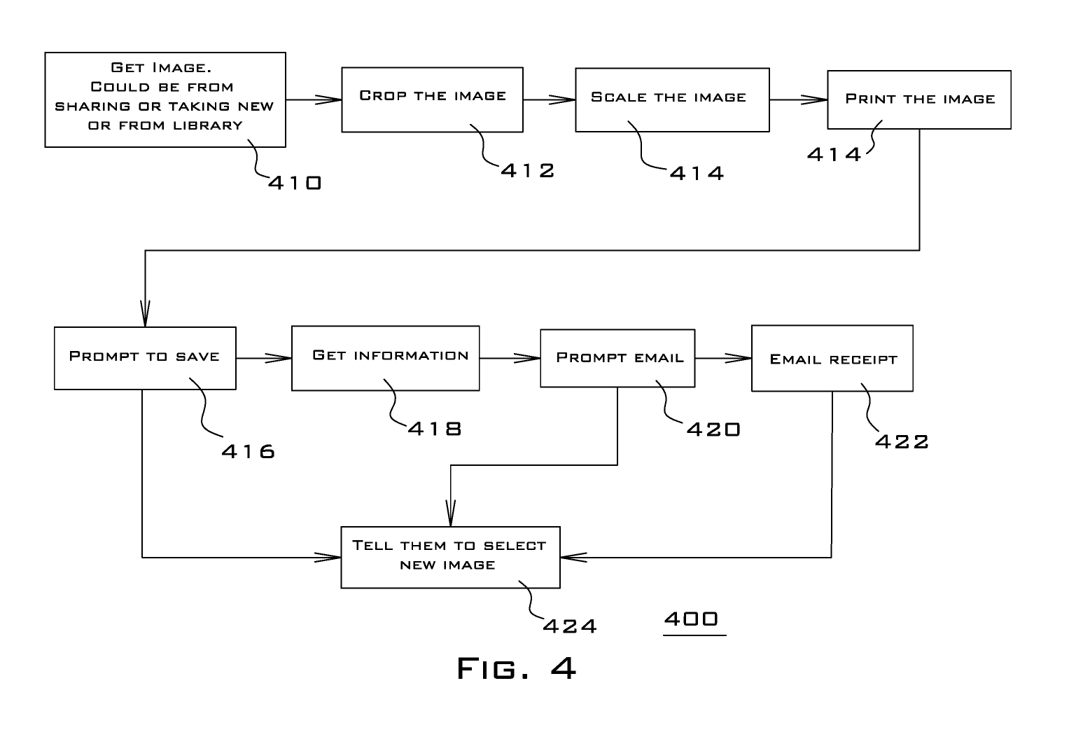

Referring now to FIG. 4, illustrates an example embodiment of a method 400 to select and configure an image on a smart device (such as a smart phone or tablet) for optical transfer or physical transfer to a substrate according to the teachings of the invention. At 410, a user upon opening an applet or App, retrieves an image, which could be from an internal library, online, or sent by a third party. At 412, the user may choose to crop or modify the image to be transferred and at 414 the user can scale the image. The image is reversed as taught above with the various “printing” methods, the user then at 414 then “prints” the image. Optionally, at 416 the user is prompted to save the image that was just “printed or transferred” into a sent file or history log at 414 and at 418 the user then retrieves information, for example a jpeg image of print just made. At 420 the user is prompted to email a jpeg image of a copy with date timestamp, etc., or a hyperlink to a historical log data, etc., thus having a physical copy, a jpeg of the image made and a complete datalog of the particulars of the image formation and then at 422 the user is prompted to email the receipt. At 424, the user is prompted to select a new image, which command can come from function 416, 420 and 422. In related embodiments, the printer app is configured for the smart device for Near Field Bluetooth and Wi-Fi functionality and USB connectivity.

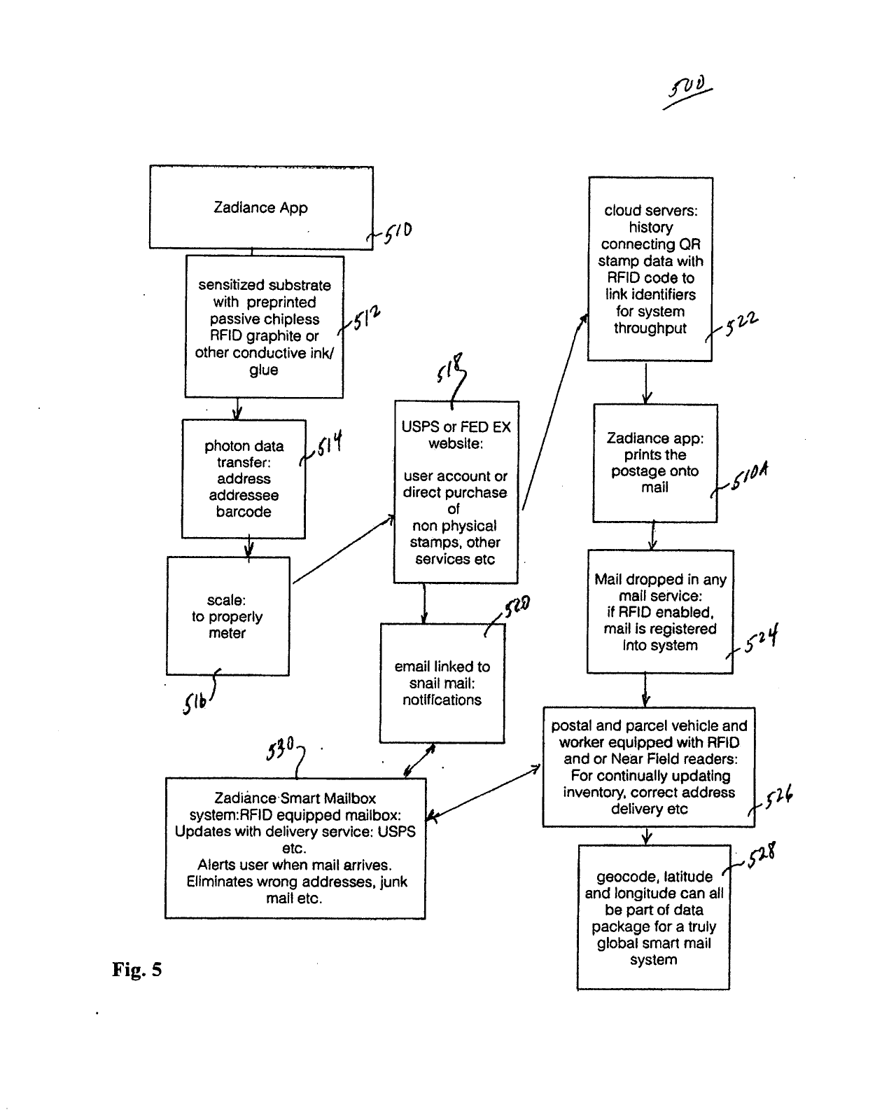

FIG. 5 illustrates a flowchart of another example embodiment of a method and system 500 to prepare a package for shipment with a commercial shipping service using RFID tracking according to the teachings of the invention. A software applet (or APP) 510 residing on a smart device such as a smartphone or handheld tablet is configured to interact with a sensitized substrate 512.

In another example embodiment, a pre-prepped area on an envelope can contain a microencapsulated load such as graphite or other conductive material that can then be exposed at the same time as the rest of the envelope and assigned a unique value corresponding to the QR stamp just printed. The exposure ruptures the microencapsulation only where needed, thus creating a circuit and/or antennae. The unruptured microencapsulation polymers continue to insulate the remaining material. App 510 of the smart device initiates a print 514 such that an envelope or package receives an address and an addressee barcode or other symbol. A scale device 516 that interfaces with App 510 (in the form of a wireless or Bluetooth interface and transducer device) is then used to weigh the package to be shipped and such data is sent to the carrier/courier website server 518 (USPS, FedEx or UPS for instance) to access the user account or direct purchase of non-physical stamps, or utility payment or other services. Optionally, there is an email link 520 that provides USPS (courier) notifications which in turn is linked to the user's smart mailbox 530 that is equipped with RFID equipment and alerts user when mail arrives, eliminates mail delivered in error and provides the user the ability to restrict junk mail. Carrier websites 518 are communicatively coupled to cloud servers 522 which provide history when connecting QR stamp data with an RFID code to link identifiers for system throughput. App 510 (box 510A) then initiates “printing” of the correct postage onto the envelope or package using the image forming system taught herein. When the mail is dropped in any mail service at 524, if the package is RFID enabled it will be automatically registered into the tracking system. At 526, postal and parcel vehicle and worker equipped with RFID and/or Near Field readers continually update inventory and check delivery address, etc. and communicate with the Smart Mailbox at 530. Optionally, system 500 provides geocode, latitude and longitude as part of the data surrounding the package being delivered.

In this and other related embodiments, unique identifiers of both barcodes and QR codes can be printed onto the paper, which can then be read by existing readers (QR code and barcodes are line of sight and can be both mechanical and optical read); depending on the application, both can be used. For example, eDigital or Zadiance™ mail or other mail and parcel services using this method can use barcodes just like the USPS to define location and zip code so as to work with their existing readers. In this example embodiment, one of the key advantages is the connection formed between the digital QR digital stamp and the carrier account such that the QR code or stamp can just be the digital stamp formed herein that is tied to a USPS, FedEx, UPS, etc. credit paid account or can include addressor, addressee, barcode and any other supplemental data that the user chooses. Since the QR code generator is a unique identifier that is data rich and we can also incorporate all of the above with additional information such as optical measure, jpeg copy of image, latitude and longitude and geocode for a truly global precision delivery system. The QR code can be a hypertext link to all the relevant data. The unique chirp of the passive chipless RFID antennae can be a minimal bit tag as it can be linked to the data rich QR code. This approach can assist in automating mail parcels as it allows the elimination all human read information of faces of mail parcels. In related embodiments, a Postal app is configured for the smart device for Near Field, Bluetooth, WiFi functionality and USB connectivity.

In the various embodiments disclosed above, although the teachings apply to both sending and receiving physical mail, the following expands on the receiving side of mail. In one example embodiment, the receiver of mail has a smart mailbox system or Near Field and/or RFID reader equipped mailbox that is online or is tied to an end user phone that can alert you when you have received mail. The chipless passive RFID AND NFC preprinted tag has a unique signature, such as utilizing the Baukhausen effect and utilizing additional materials to clarify the signal. Printing directly onto the sensitized substrate (envelope, etc.) helps to alert user of incoming inventory or mail or when you are expecting to receive packages from a courier, which may require a signature when leaving the package. Signature can be sent by a smart phone and the same App would notify the recipient and shipper immediately if the package was thereafter moved. Mail and parcels will be scanned using the App and teachings described herein and would alert a mailman or delivery service of incorrectly addressed or incorrectly delivered packages (wrong address, wrong suite or apartment, etc.). The mailman or delivery person would also have a scanner equipped with one of the Apps described herein to perform a final check on the mail. A simple beep alerts the driver to wrong address, for instance, as the integrated system described herein would tie all matters relating to shipping as described herein thus creating the first complete data rich throughput system. Cluster mail boxes, post office boxes, mail services etc., all of these systems can be hard wired or be interconnected and homes offices and/or battery operated CBU and PO boxes would only turn on when the mailman or delivery person's scanner is nearby.

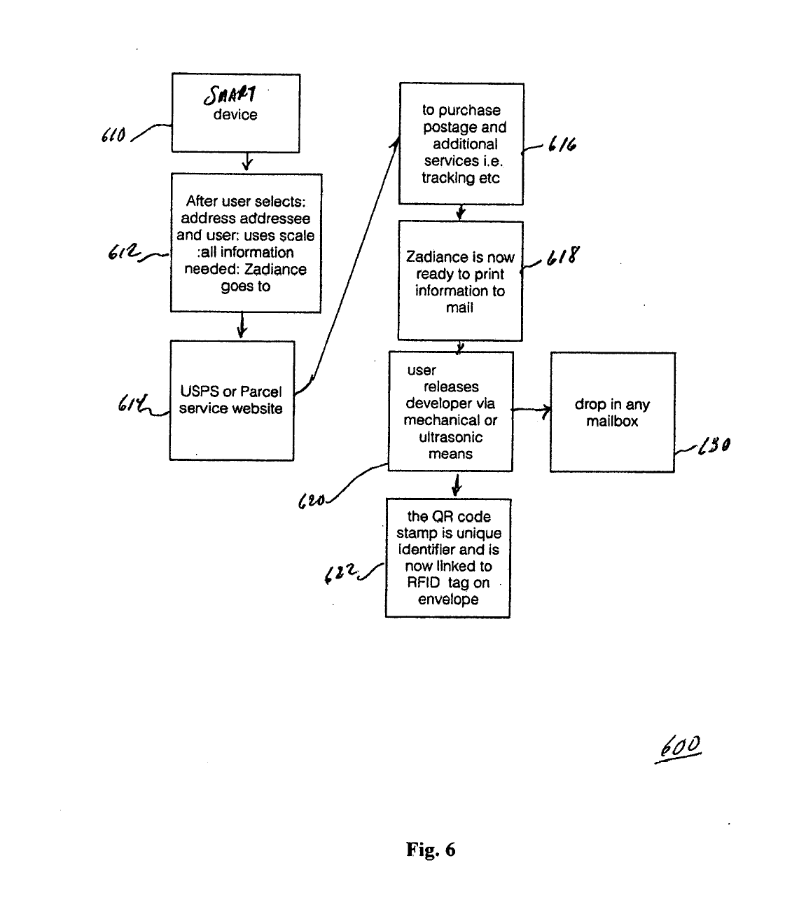

In a more detailed embodiment, there is illustrated in FIGS. 6-8 an example embodiment of a system comprise of 600, 700 and 800 for using a smart device to address a package for shipping, purchasing postage and linking a QR code with an RFID tag on the package according to the teachings of the invention. In particular, a smart device 610 with an image forming App is initiated by user at 612 to selecting mailing options and details and accesses scale function to determine proper postage. Next the App accesses the parcel vendor website at 614 to be able to purchase postage and additional services at 616 and at 618 the App is ready to “print” on the envelope the mailing information, postage and tracking information. At 620, the image is “developed” after exposure by releasing developer using mechanical (friction) or ultrasonic waves to disperse the developer solution and then at 622, the QR code stamp (a unique identifier) is formed on the envelope and is now linked to RFID tag on the envelope. At 630 the user drops the envelope into the mailbox.

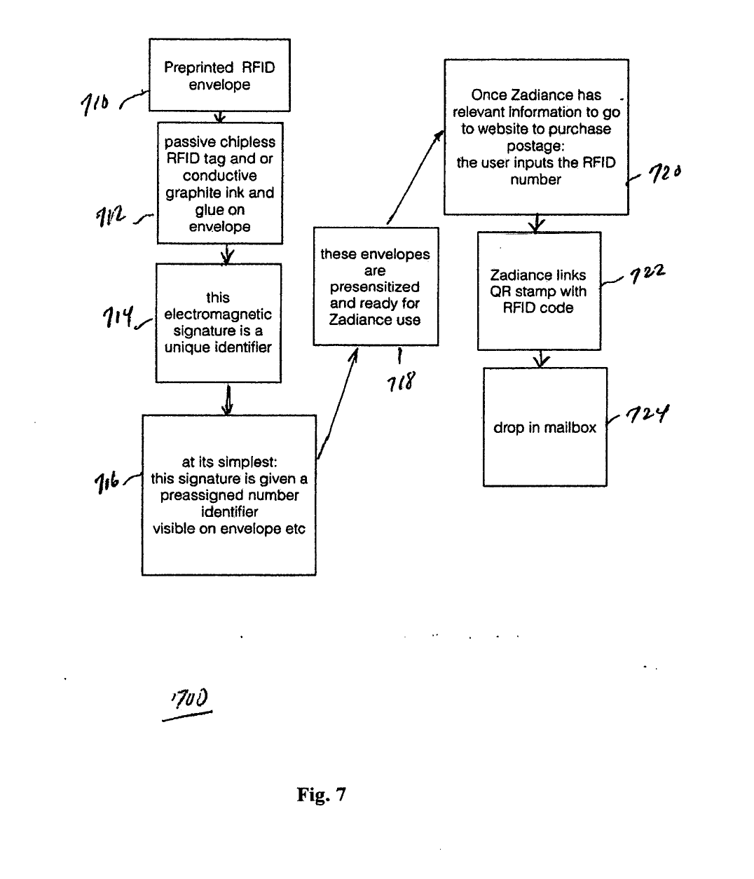

Referring now to FIG. 7, an RFID linking to QR code stamp process 700 includes a preprinted RFID envelope at 710 that includes at 712 passive, chipless RFID tag comprised of conductive graphite ink and glue on the envelope which becomes at 714 an electromagnetic signature or a unique package identifier. At 716, the code on the package is given a preassigned number identifier that is also visible on the envelope. Since at 718 the envelopes are pre-sensitized, they are ready for use for quick addressing and mailing. At 720, the App accesses the USPS website to purchase postage once the package includes the relevant information needed to make the connection. At 722, the App links the QR stamp with the RFID code and then the user at 724 drops the envelope in the mailbox.

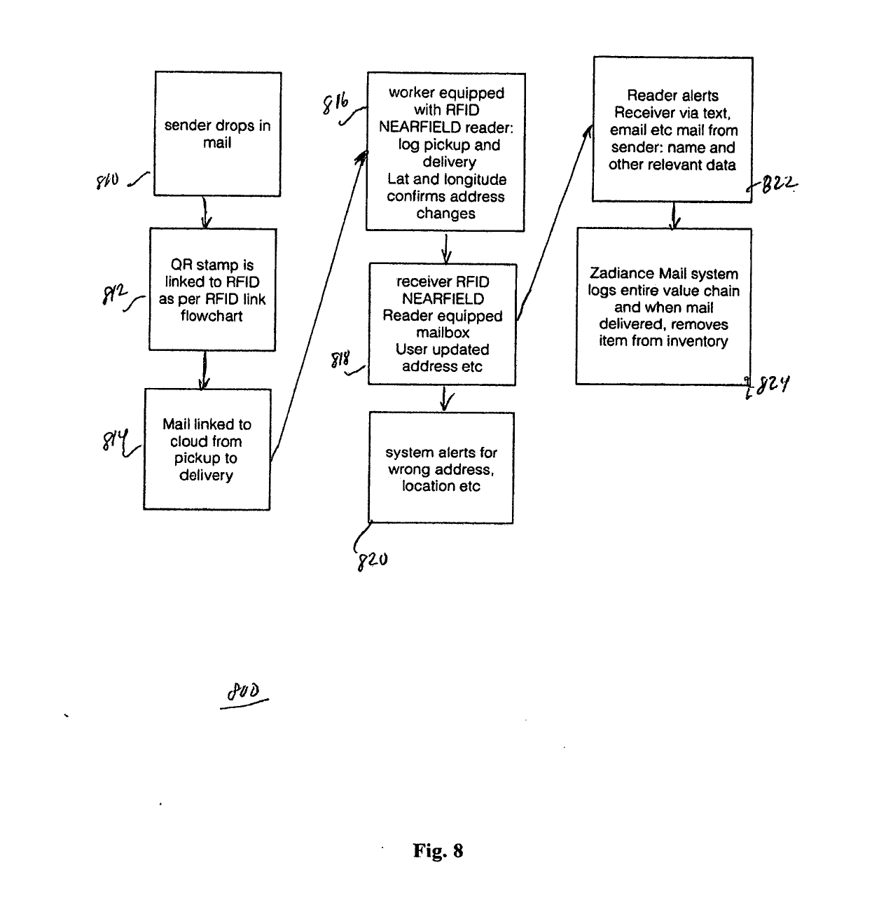

Referring now to FIG. 8, a home mailbox system with user alerts 800 is provided which includes a step at 810 by which a user drops an envelope in the mail and at 812 a QR stamp is linked to an RFID as per the RFID flowchart. At 814, the mail is then linked to the cloud and tracked from pickup to delivery and similar to system 550, a work at 816 is equipped with RFID reading equipment and confirms address using latitude and longitude coordinates. System 820 alerts if there is an incorrect address and at 822 the reader alerts the Receiver via text or email the relevant ID data needed. At 824, the system removes the delivered package from the tracking system.

The aforementioned teachings would immediately eliminate many weaknesses in the mail and parcel delivery systems by reducing fraud and allows the Postal Service and courier enterprises to have a complete throughput of service thus creating a better user experience. In one example embodiment, a smart mailbox is envisioned having user defined settings (what types of mail accepted; address; recipients; new or temporary residents, etc.) that are easily updated. Further, the smart mailbox system would be tied to an end user device to automate address changes or corrections, deal with junk mail, and deal with types of mail requiring digital signing. An integrated or incorporated RFID reader would send a beep alert to let the post man know if wrong mail is being delivered. The Smart mailbox can also accept certified packages and parcels needing a digital signature have a notice sent to the recipient so that they can sign on their smart phone for delivery acceptance (the smart mailbox suffices for signature and have a text sent to receiver). With a smart mailbox reader to read the chipless passive RFID or NFC printed envelopes, this lets post office know of delivery with most of these functions being controllable with a smart phone and App. In other instances the user with the App, smart device and smart mailbox, can easily inform USPS that they are gone for week or to hold the mail or change an address or advice another courier service of other matters (billings shipping delivery addresses; pickup time; pickup personnel; inventory and recognize mail with a reader; beeps if a wrong address is delivered; improved security and reduction of fraud; etc.), thereby having a fully integrated physical mail service with digital interface, where the Sender knows mail has arrived and the Receiver knows has been delivered and able to manage mail inventory history on their smart phone.

In a related embodiment, the smart mailbox has its own chipset with an IP address that is WiFi connected or may use passive near field or RFID readers with an identifier circuit. In yet another embodiment, cyanotype and metallic photosensitive circuits and other photosensitive conductive materials are printed directly onto envelopes, packages, etc. resulting in or appearing as passive RFID or passive Near Field enabled items. These chips or circuits may contain relevant information of sender and receiver so that the mailman or delivery man's scanner can check at a glance if all mail is correct and provides an alert if there is an error due to the proximity to the circuit or mailbox. Thereafter, the App advises recipient of mail in the mailbox.

In a related example embodiment, the technology and concepts described herein involve computer controlled packets of light as a form of communication and data transfer. The advent of OLED, UVOLED, AMOLED and now Quantum DOT display technology offer true pixel on/off capability. The pixel is the smallest addressable unit in a display. Similar to the smallest addressable unit in any language, the pixel can now be the basis for a binary pixel-based data transfer protocol, thus enabling the binary communications platform described herein in order to provide computer-enabled photon control and manipulation of information and matter that is an interface between a digital medium and a physical medium. In short, individual pixel control on a display is now possible, representing digital 1 and 0's, such that matter and information can now be composed of light on/off pixel sequences. A new computer language based on binary and converting commands into pixel on/off sequences and packets is now provided. Individual pixels (in the form of photons) can provide infinite data transmission as it facilitates individual pixel by pixel control of light (pixel on/off represents bits/bytes or photon pixel packets). In one embodiment, the pixel on/off sequences facilitate sequences for bits and bytes, similar to Morse code. The Display as Data Transfer facilitates this type of data transfer. All of this communication with other devices can now be from an electronic display device without the display device being connected physically or wirelessly to the receiving device or printer or network.

In a related example embodiment, pixel-by-pixel control of physical matter such as light sensitive polymers for 3D printing and chemical mixes for substrates can be manipulated with the OLED AMOLED and Quantum Dot displays. The internet and digital world can now control the unconnected physical world of matter via the power of light as pixels (and the photons emitted therefrom) are the bridge between the two mediums and is blending the line between virtual reality and physical reality, i.e., Physical state vs. Digital state.

An advantage of using photon pixel “computer language” is that it provides a high level of security (and potentially high throughput) in that it is not connected to the internet or a network nor is it formatted as typical software language, such as Java, thereby providing an almost impenetrable defense against standard malware and viruses. Intelligent pixels are configurable as light communication with air barriers providing malware-free transfer of data from one smart device to another. In one example, an onscreen static image transfer is possible as an image onscreen is not a format and is instead merely an image that can be printed to any sensitized substrate, therefore making this digital to physical transfer malware-free. A simple JPEG of a physical copy just made completes the digital to physical to digital transfer. In a related embodiment, a faster more elegant system is to have a direct device to device transfer. No web/internet, Bluetooth or any other connection is required to execute the image/data transfer and further a static image on the device screen has no malware. In one example, Device A has an image on its display that is to be transferred or transmitted as it faces a receiving Device B, which reads the image from Device A and replicates it in Device B, using digital to photon coding.

In another related embodiment, a transfer of large amounts of images/data can be completed via the use of a movie, which are JPEG and MOVIE formatted backups, images that are not in the programs they originated from and as such cannot be edited, modified, etc. until placed back into the original program. In this example, a program is configured for a receiver device to recognize what program image came from, such as pages, doc etc., and then the image is put back into same program. One option is to send the image to a universal word processor, such as Google docs, etc. The receiving device then reads the pixel on/off and sequencing language and replicates pixel commands and converts the commands back into the program language. In this example, the receiving device does not have the ability to send data back to the sending device or computer and likewise the sending computer or device does not have the capability to receive data. In this example, the sending device is only accessed by operators (and/or devices) that are completely unconnected to a computer or a network that can control anything that is connected. A simple on/off switch, curtain or camera shutter can be used as the physical stop gap.

In one example embodiment, the pixel-based binary computer communication described herein is similar to the Naval system of ship to ship light commands (a computer version of Morse code using bits and bytes to photons and pixels (1's and 0's). So as to speed up communication using Morse code, in this example embodiment, a subroutine can be developed to speed up the coding of letters and words into light pulses from the pixels in the sending device and then use the same program in the receiving device to decode the light pulses received from the pixels from the sending device. Source Data, in this example, cannot be corrupted or viewed or accessed by anyone except those allowed into room. Many configurations are possible so as to allow 1 way; 2 way; partial and full 2 way communications. Any system other than 1 way will require scrubware to monitor and clean data. Government, personal networks, airline flight computers, cars, NSA, military, cloud networks, and any entity that needs protection can take advantage of these teachings. In one example, cloud storage facility web information is transmitted in using the digital/physical interface system described herein, which can then work in reverse in going back out to web.

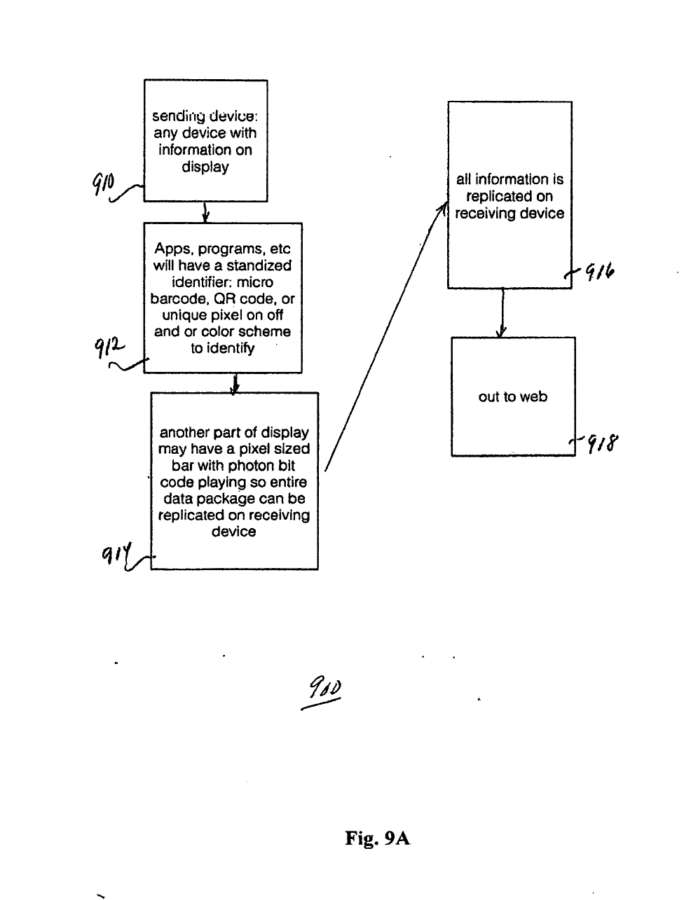

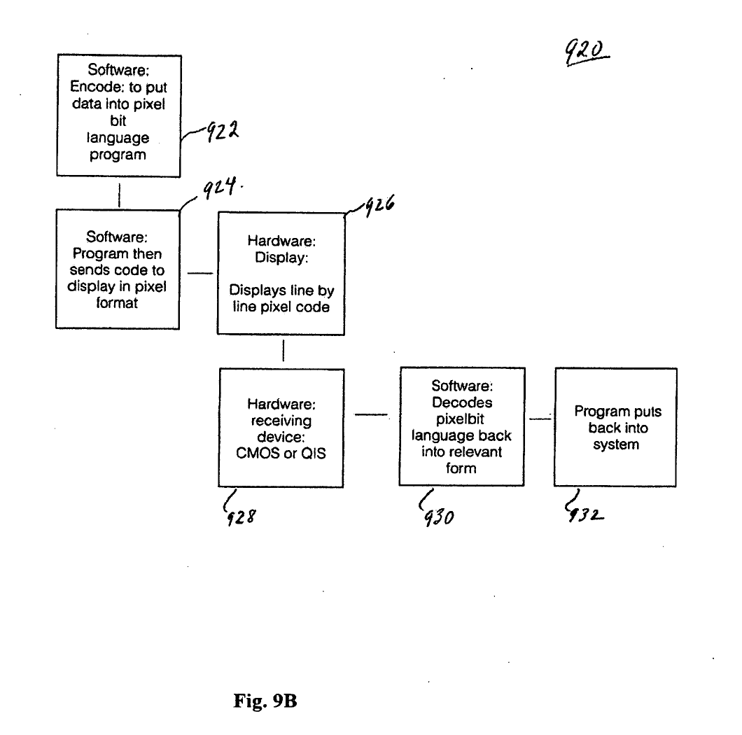

Binary Communicator—in this example embodiment (FIG. 9B), pixels are used as bits that can be configured to turn the Internet of Things (IoT) opposite its normal arrangement. What if we can establish a “no connectivity” manner to identify what is on the display and also the internet? A receiving machine can see what is in front of it but cannot identify what it is seeing. By using an industry standardized system of identifiers, such as a small QR code, barcode or simply some pixels in a unique on/off binary pattern, different colors, each app and program, web page on the display and anything on the net can be identified. Hence a receiver sees the information on the display and knows to replicate, for example, the Apple Pages document into an Apple Pages document. When the smart device is equipped with a binary communicator program, if an Apple Pages document is open on one visual display, the display can send the file to the receiving device.

In one example embodiment, as illustrated in FIGS. 9A and 9B a method 900 and a system 920 is described for sending a selected image, file or data set via binary code from one smart device to another according to the teachings of the invention. At 910, a sending device is provided that includes a display for visual information. At 912, the sending device includes Apps, programs, etc. and will include a unique tracking symbol (QR code, barcode, unique on/off pixels, etc.) while at 914 in another part of the display a pixel sized bar with photon bit code is streaming so the entire data package can be replicated on the receiving device. At 916, all information is replicated on the receiving device and then directed out to the web at 918. With respect to system 920, a microprocessor with memory device initiates a software App 922 to encode and put data into the pixel bit language program and then at 924 software app 922 sends the code to a display in pixel format. Display (hardware) 926 then displays line by line pixel code while display (hardware) 928 acting as a receiving device (such as a CMOS or QIS) receives the code and uses its own software to decode pixelbit language back into relevant form at 930. At 932, the program puts the pixelbit back into the system.

In another example, displays are configurable to provide infinitely scalable communications. The entire display surface is a binary, pixel by pixel, line by line, pixelbit communications device. There are just over 2 million pixels on each TV or monitor (1,920×1,080), and with a defined hertz refresh rate, hence data transfer is theoretically unlimited. The new paper thin, scalable 4K and 8K TVs will truly allow infinite data transfer. Quantum Dots can channel individual photons providing infinitely scalable interfaces and providing information at the speed of light (pixel communication) in the form of photon bits (and later photon bit programming), similar to binary using bits and bytes in communication. In this case the photon is the basic packet of light or is the equivalent of a bit, while the pixel is a point of light on a device display. Short and long pauses of light are similar to dots and dashes in Morse code, thereby providing a new method for the internet to securely communicate combined with its ability to be infinitely scalable, varying display sizes, varying colors and frequencies. Therefore, two devices, one being a display and the other being a receiver, can face each other with one sending bits and bytes as light flashes to the receiving device. This communication can be one way or a modified version of 2-way. The receiver can consist of readily available CMOS and new Quanta Image Sensor (QIS) technologies as the QIS can read over 1 billion pixels at once.

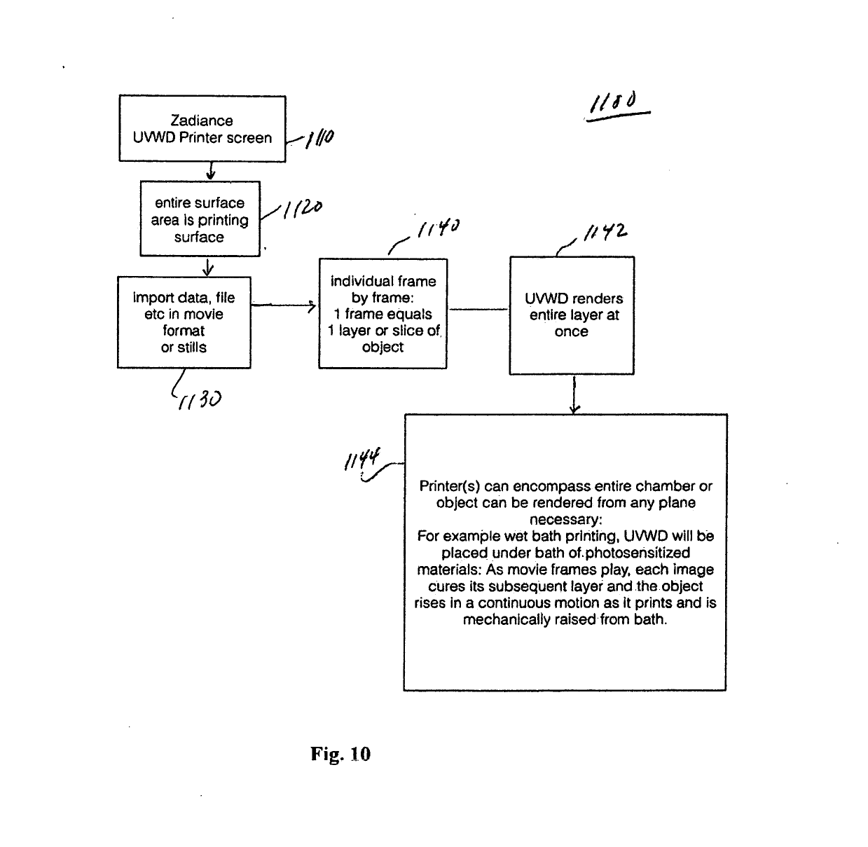

Referring now to FIG. 10, there is illustrated an example embodiment of system 1100 and method of performing 3-D printing using pixel by pixel control and image projection using an specific wavelength display according to the teachings of the invention. With respect to Display as Printer technology, displays, such as an Ultraviolet Wavelength Display Printer or UVWD printer have been created to utilize the true on/off capability of OLED pixel control to yield high resolution prints for 2D and 3D printing and for 2D and 3D data transfer with pixel language. Black is pixel off so diazo does not react, while Purple is pixel on, which burns off the diazo. About UVA 360 nm to about 410 nm is the range of preferred wavelengths and when used properly it would not be harmful but can be very useful. In a related embodiment, this type of display serves as a safe Vitamin D delivery system in a tanning both for health benefits and can optimize plantbots.

Utilizing the pixel by pixel Display as Network for Data Transfer technology as described herein allows data transfer without physical means, without being hard wired or needing connectivity, without electronic or printer and without integrating physically to a digital network in order to manipulate matter and data ensures secure data, for example, the blockchains of private permissioned ledger and distributed ledger technology can be securely offline thus ensuring further user protections. For QR money, the base paper can be the world's first currency backed by citizens without the need for government or other third parties such as banks, or can be national based: US, NZ etc. only the surface will be sensitized to print. This preserves the look and feel of what is common and hard to replicate. The base and face of this form of money could be a giant QR Code. In another related embodiment, the abovementioned teachings facilitate pixels for printing 2D and 3D printing and circuitry and 2D and 3D circuitry on substrates.

In this example embodiment, system 1100 includes a UVWD printer screen 1110 having a display 1120 configured to use the entire surface as a printing surface. System 1100 includes a microprocessor with memory for storing data such that the data is imported therefrom in the form of JPEG stills or in a movie format 1130. At 1140, individual frame by frame is pulled from memory as 1 frame equals 1 layer or slice of an object. At 1142 UVWD printer 1110 renders or continuously forms the entire layer at once. At 1144, UVWD printer 1110 can encompass the entire chamber or object can be rendered from any plane necessary. In one example of 3D printing, in wet bath resin printing the UVWD printer will be placed under the bath of photosensitized materials so as the movie frames play, each image continuously cures its subsequent layer and the object rises in continuous motion as it prints and is mechanically raised from the bath.

In another related example embodiment, a specific wavelength display high precision instrument is used for 3D printing by having the SWD display under and projecting up through the wet bath such that the object rises of the bath as it is forming. In this example, UV light cures photosensitive materials from the bottom of the bath so as the material cures the next image slice appears ready for formation and curing, and so and so forth. In this method, the UV or other wavelength can be optimized for the material being used and it can be used for both 2D and 3D printing. In a related embodiment, LED, OLED, Quantum Dot and other displays can be configured and used in a similar fashion, as pixel by pixel control of light is now possible. As the size of the display increases, larger images leading to larger objects can be “printed” leading increased throughput and achievement of economies of scale.

In another embodiment, the smart display device instantly reacts with photopolymers that serve as the basis for 2D and 3D printing. The UVA light from the display will also react with diazo tech instantly for image copies. The UVWD printers can be any size and can be connected in a network with its own address. Further the UVWD printer can be connected as a second monitor using an HDMI cable thereby being legacy printer driver and format free. As TV's continue to become bigger, better and thinner, the size of print capability continues to expand dramatically. In the case of 3D, the SWD printer will allow an unprecedented scale of useable printing surface and throughput and will be able to use an image onscreen or a JPEG image for single prints. For both 2D and 3D a movie format can be used for 2D multipage print jobs and for 3D printing a schematic file as an entire layer at a time as each movie frame plays thus yielding both scale and speed never before seen.

In one example experiment, LEDs were tested using visible light from high output flashlight devices having a spectrum of about 400 nm, 450 nm and 500 nm and 550 nm. Observations noted on the brightest settings were the generation of an instant reaction on the substrate receiving the image to be transferred. It was observed that as the wavelength increases of the light generated by the display, the reaction on the substrates slows down and the image transfer is slower as well, but can be overcome by light intensity. This observation can include all displays such as non-backlit LED, OLED, AMOLED and Quantum Dot, and so forth which have this capability. In turn, a visible light display with an applet as described herein can be modified to choose the proper wavelength(s) and brightness levels to react to the chemistry or coating of the substrate. Additionally, to the applet described herein of brightest contrast levels and black for true pixel off condition, the applet can be configured to choose a given wavelength, such as 500 nm and black to connote for pixel “off” to instantly “print” a black and white image. In a related embodiment, UVA is incorporated into modern display technology, such as the 365 nm to 400 nm wavelengths to speed up reaction times. However, wavelengths closer to 410 nm and above that are visible may be safer to use commercially.

With respect to “printing” technologies disclosed herein, a diazo or microencapsulated load substrate coating application technique for generating an image or print for displays is described herein for providing precise conductive prints, color and multi-color prints using specially sensitized paper using a layering technique. In one example embodiment of a “printing” App, a full color copy App combines all the data of: timed exposures, wavelength control modulation and algorithms to faithfully reproduce any image on screen. In one example, the grid exhibits the X Axis includes CMYK while the Y Axis also includes CMYK. Each line is one or more molecule wide with encapsulated amine developer or other load between rows. In a related embodiment, the grid is configured for multi-coating for several layers of colors. There can be a base coating underneath for additional resolution clarity filling and/or an additional layer of encapsulated amine. In one example, individual diazo colors: a custom mix is used for contrast for both black and white and color imaging.

In other related embodiments, to speed the diazo exposure the coatings can be varied to have lower concentrations for faster burn off, and or to have a reagent such as AIBN incorporated into mix so as to speed exposure reaction. For image development, incorporate a developer and image stabilizer within a microencapsulated shell using ammonium hydroxide or other alkyl amine DETA, for a convenient pressure released image development, such as by friction over the surface of the substrate to release the encapsulated amine. Paper made with the microencapsulated coating facilitates 2D printing anywhere and at any time. In yet another related embodiment, the encapsulated developer is incorporated directly into the substrate coating formulation, thereby putting all of the chemistry on the substrate in one step and easy exposure, such that the developer is pressure-released using ultrasonic waves (to break up the encapsulated amines) for image development to produce a finished “copy.”

Examples of Exposure and Development with Diazo Compounds Commercially available paper by Dietzgen and Cannon was screened by exposing the material to long wave ultraviolet light at 365 nm (LWUV), short wave ultraviolet light at 254 nm (SWUV), an Artograph LED lightpad (LED), and OLED light from a Samsung Galaxy Tab (OLED). LWUV, SWUV, and LED utilize a printed screen with a symbol on it. OLED used an illuminated image of the symbol at the maximum brightness of the OLED tablet.

From these benchmarks several light-activated chemicals were coated on the paper front or back by painting or aerosol spray in water or organic solvent at varying concentrations, typically 1%, 10% or 50% unless otherwise indicated. They were allowed to dry absent from light. The treated paper was exposed to the light sources for varying amounts of time, typically 5 min., 1 min., and 30 sec. Upon completing exposure, the paper was developed by painting, spraying, or exposing to the vapor of several alkaline materials, including commercial developer (mixture of alkyl amines and solvent), alkyl amines, and ammonium hydroxide. The paper was allowed to dry and the level of blue/white contrast was observed. Combinations of exposure and treatment with the light-activated chemicals were also investigated and will be described further.

### Control Experiments:

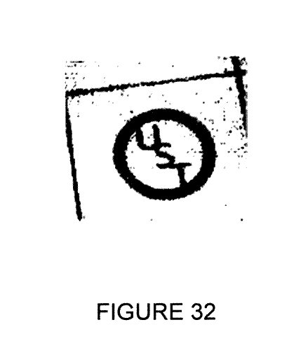

Dietzgen and Cannon paper were tested under the same conditions. Both were comparable, though the Dietzgen paper seemed to give slightly better results hence the remainder of the experiments were conducted primarily on the Dietzgen paper. The results were judged qualitatively in three main categories: sharpness of image, contrast between negative and positive areas, and rate of change versus control conditions. For instance, LWUV (low wavelength ultraviolet) exposure of untreated Dietzgen paper for 30 seconds results in the image shown in FIG. 32. Sharpness for the image would be rated a 4 of 5.

Contrast between negative and positive areas would be given a 4:1 ratio. The blue (dark) is nearly the maximum darkness if the paper was unexposed and the white is nearly pure white so the number is low. A higher ratio suggests a better contrast.

Rate is relative to a control and this would be the LWUV control. This sample would be a 4/4:1/n/a and would be the best example to achieve. To achieve a 4/4:1/n/a rating, the following is needed per light source on untreated paper.

### LWU

### V: 30

sec.

### SWU

### V: >5

min

### LED

:5
min

### OLED: >15 min

For each light source, treated paper that neared a 4/4:1 rating in any time less than those listed above would be an acceleration from the control.

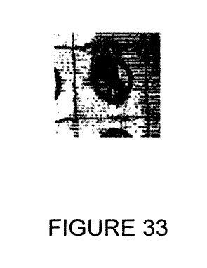

An example comparing LWUV and using LED light would be as follows: Untreated paper, LED lightpad, 5 minutes, developer (see FIG. 33). Sharpness for the image would be rated a 4 of 5.

Contrast between negative and positive areas would be given a 4:1 ratio. The blue (dark) is nearly the maximum darkness if the paper was unexposed and the white is nearly pure white so the number is low. A higher ratio suggests a better contrast.

Rate is relative to a control and this would be comparable to the LWUV above. The rate to achieve this level of contrast is 10 times greater than that of the LWUV exposure or 0.1 times the rate. The greater the rate the better compared to the control.

This sample would be a 4/4:1/0.1 compared to the LWUV sample.

Sensitized paper was made by treating with the following light-sensitive chemicals: 2,2,2′-azobisisobutyronitrile (AIBN), Benzoyl Peroxide (BP), Riboflavin (RIBO), Ru(BPY)₃Cl₂ (RUBPY), and potassium antimony tartarate (TE) in varying concentrations. The results are summarized as follows. Rates are approximations, and anything greater than one suggests the sample is better than the control with that amount of exposure.

AIBN versus untreated paper with LED light

| | | | Sharp- | Con- | | |
|---|---|---|---|---|---|---|
| Conc. | Time | Light | ness | trast | Rate | Notes |
| 0 | 5 min | LED | 4 | 4:1 | N/A | |
| 0 | 2 min | LED | 4 | 4:2 | N/A | |
| 0 | 30 sec | LED | 3 | 4:3 | N/A | |
| 1% | 2 min | LED | 4 | 4:1 | 2.5 | Comparable contrast to 5 |
| | | | | | | min untreated in 2 min |
| 1% | 1 min | LED | 3 | 3:1 | 5 | Blue slightly faded but |
| | | | | | | good contrast |
| 1% | 30 s | LED | 3 | 3:2 | 2 | Comparable to 1 min |
| | | | | | | untreated |
| 10% | 5 min | LED | 4 | 4:1 | 1 | |
| 10% | 1 min | LED | 3 | 4:2 | >1 | Light blue background. |
| | | | | | | Lines distinct but not |
| | | | | | | sharp. |
| 10% | 30 sec | LED | 2 | 3:2 | −1 | Similar or slightly better |
| | | | | | | than 30 sec untreated |
| 50% | | LED | | | | This concentration of |
| | | | | | | AIBN made the image |
| | | | | | | splotchy |

AIBN versus untreated paper with OLED

| | | | Sharp- | Con- | | |
|---|---|---|---|---|---|---|
| Conc. | Time | Light | ness | trast | Rate | Notes |
| 0% | 5 min | OLED | 3 | 5:2 | N/A | |
| 0% | 1 min | OLED | 1 | 4:3 | N/A | Symbol outline barely |
| | | | | | | visible against |
| | | | | | | background |
| 0% | 30 sec | OLED | 1 | 5:4 | N/A | Symbol outline barely |
| | | | | | | visible against |
| | | | | | | background |
| 1% | 5 min | OLED | 2 | 4:2 | >1 | Z visible in symbol |
| | | | | | | with faded blue. Lines |
| | | | | | | not sharp. |
| 1% | 1 min | OLED | 1 | 4:3 | N/A | Symbol outline barely |
| | | | | | | visible against |
| | | | | | | background |
| 1% | 30 sec | OLED | 1 | 5:4 | N/A | Symbol outline barely |
| | | | | | | visible against |
| | | | | | | background |
| 10% | 5 min | OLED | 3 | 3:1 | >1 | Near white back- |
| | | | | | | ground with symbol |
| | | | | | | visible. |
| 10% | 1 min | OLED | 2 | 3:2 | >1 | Z and diamond slightly |
| | | | | | | visible |
| 10% | 30 sec | OLED | | | | |
| 50% | | OLED | | | | This concentration of |
| | | | | | | AIBN made the image |
| | | | | | | splotchy |

BP versus untreated paper with LED

| | | | Sharp- | Con- | | |
|---|---|---|---|---|---|---|
| Conc. | Time | Light | ness | trast | Rate | Notes |
| 0 | 5 min | LED | 4 | 4:1 | N/A | |
| 0 | 2 min | LED | 4 | 4:2 | N/A | |
| 0 | 30 sec | LED | 3 | 4:3 | N/A | |
| 1% | 5 min | LED | 4 | 4:1 | N/A | |
| 1% | 1 min | LED | 4 | 3:1 | >1 | |
| 1% | 30 sec | LED | 2 | 3:2 | >1 | Closer to white |
| | | | | | | background than |
| | | | | | | untreated 30 sec |
| 10% | 5 min | LED | 2 | 2:1 | >1 | Almost no color |
| | | | | | | remaining. 10% BP |
| | | | | | | bleaches the whole |
| | | | | | | sample. |
| 10% | 1 min | LED | 1 | 2:1 | >1 | See above |
| 10% | 30 sec | LED | 1 | 2:1 | >1 | See above |
| 50% | 30 sec | LED | 1 | 1:1 | >1 | See above |

BP versus untreated paper with OLED

| | | | Sharp- | Con- | | |
|---|---|---|---|---|---|---|
| Conc. | Time | Light | ness | trast | Rate | Notes |
| 0% | 5 min | OLED | 3 | 5:2 | N/A | |
| 0% | 1 min | OLED | 1 | 4:3 | N/A | Symbol outline barely |
| | | | | | | visible against |
| | | | | | | background |
| 0% | 30 sec | OLED | 1 | 5:4 | N/A | Symbol outline barely |
| | | | | | | visible against |
| | | | | | | background |
| 1% | 5 min | OLED | 3 | 3:1 | >1 | Closer to white back- |
| | | | | | | ground at 5 min |
| 1% | 1 min | OLED | 1 | 3:2 | >1 | Symbol outline barely |
| | | | | | | visible against back- |
| | | | | | | ground, but closer |
| | | | | | | to white |
| 1% | 30 sec | OLED | 1 | 3:3 | >1 | Symbol outline barely |
| | | | | | | visible against |
| | | | | | | background |
| 10% | | | | | | All exposures with |
| | | | | | | 10% are degraded and |
| | | | | | | not well contrasted. |
| 50% | | | | | | 10% ruins paper, so |
| | | | | | | 50% not run |

RIBO versus untreated paper with LED

| | | | Sharp- | Con- | | |
|---|---|---|---|---|---|---|
| Conc. | Time | Light | ness | trast | Rate | Notes |
| 0 | 5 min | LED | 4 | 4:1 | N/A | |
| 0 | 2 min | LED | 4 | 4:2 | N/A | |
| 0 | 30 sec | LED | 3 | 4:3 | N/A | |
| 1% | 30 sec | LED | 4 | 3:1 | >1 | Though results are |
| | | | | | | slightly better with |
| | | | | | | riboflavin treated, |
| | | | | | | the background remains |
| | | | | | | slightly yellow at 1% |
| 10% | 30 sec | LED | 3 | 3:1 | >1 | Though results are |
| | | | | | | slightly better with |
| | | | | | | riboflavin treated, |
| | | | | | | the background remains |
| | | | | | | bright orange/yellow |
| | | | | | | with splotches at 10% |

TE versus untreated paper with LED -
Maximum solubility in water −6%

| | | | Sharp- | Con- | | |
|---|---|---|---|---|---|---|
| Conc. | Time | Light | ness | trast | Rate | Notes |
| 0 | 5 min | LED | 4 | 4:1 | N/A | |
| 0 | 2 min | LED | 4 | 4:2 | N/A | |
| 0 | 30 sec | LED | 3 | 4:3 | N/A | |
| 6% | 5 min | LED | 3 | 4:1 | N/A | Similar to untreated - |
| | | | | | | no color change |
| 6% | 1 min | LED | 3 | 4:2 | N/A | Similar to untreated - |
| | | | | | | no color change |
| 6% | 30 sec | LED | 2 | 3:2 | >1 | A little lighter than |
| | | | | | | untreated - no color |
| | | | | | | chan [symbol] e |

[symbol]

indicates data missing or illegible when filed

TE versus untreated paper with OLED -
Maximum solubility in water −6%

| | | | Sharp- | Con- | | |
|---|---|---|---|---|---|---|
| Conc. | Time | Light | ness | trast | Rate | Notes |
| 0% | 5 min | OLED | 3 | 5:2 | N/A | |
| 0% | 1 min | OLED | 1 | 4:3 | N/A | Symbol outline barely |
| | | | | | | visible against |
| | | | | | | background |
| 0% | 30 sec | OLED | 1 | 5:4 | N/A | Symbol outline barely |
| | | | | | | visible against |
| | | | | | | background |
| 6% | 5 min | OLED | 3 | 4:2 | N/A | No great improvement |
| | | | | | | from untreated |
| 6% | 1 min | OLED | | | | No visible contrast |
| 6% | 30 sec | OLED | | | | No visible contrast |

RUBPY versus untreated paper with LED

| | | | Sharp- | Con- | | |
|---|---|---|---|---|---|---|
| Conc. | Time | Light | ness | trast | Rate | Notes |
| 0 | 5 min | LED | 4 | 4:1 | N/A | |
| 0 | 2 min | LED | 4 | 4:2 | N/A | |
| 0 | 30 sec | LED | 3 | 4:3 | N/A | |
| 1% | 5 min | LED | 3 | 4:1 | N/A | Similar or slightly better |
| | | | | | | contrast to untreated, but |
| | | | | | | orange background |
| 1% | 1 min | LED | 4 | 3:1 | >1 | Similar or slightly better |
| | | | | | | contrast to untreated, but |
| | | | | | | orange background |
| 1% | 30 sec | LED | 2 | 3:2 | 1 | Very washed out, lines |
| | | | | | | not distinct |
| 10% | 5 min | LED | 4 | 3:1 | >1 | Similar or slightly better |
| | | | | | | contrast to untreated, but |
| | | | | | | bright orange background |
| | | | | | | remains |
| 10% | 1 min | LED | 2 | 2:1 | >1 | Very washed out, lines |
| | | | | | | not distinct, orange |
| | | | | | | background |
| 10% | 30 sec | LED | | | | Symbol hardly visible |
| | | | | | | due to orange back- |
| | | | | | | ground |

RUBPY versus untreated paper with OLED

| | | | Sharp- | Con- | | |
|---|---|---|---|---|---|---|
| Conc. | Time | Light | ness | trast | Rate | Notes |
| 0% | 5 min | OLED | 3 | 5:2 | N/A | |
| 0% | 1 min | OLED | 1 | 4:3 | N/A | Symbol outline barely |
| | | | | | | visible against |
| | | | | | | background |
| 0% | 30 sec | OLED | 1 | 5:4 | N/A | Symbol outline barely |
| | | | | | | visible against |
| | | | | | | background |
| 1% | 5 min | OLED | 2 | 4:1 | >1 | Negative space is |
| | | | | | | closer to white than |
| | | | | | | untreated, light |
| | | | | | | orange tint to |
| | | | | | | background |
| 1% | 1 min | OLED | | | | Very washed out, lines |
| | | | | | | not distinct, light |
| | | | | | | orange background |
| 1% | 30 sec | OLED | | | | Very washed out, lines |
| | | | | | | not distinct, light |
| | | | | | | orange background |
| 10% | 5 min | OLED | 3 | 4:1 | >1 | Negative space is |
| | | | | | | closer to white than |
| | | | | | | untreated, orange |
| | | | | | | background |
| 10% | 1 min | OLED | | | | Very washed out, lines |
| | | | | | | not distinct, orange |
| | | | | | | background |
| 10% | 30 sec | OLED | | | | Very washed out, lines |
| | | | | | | not distinct, orange |
| | | | | | | background |

Treating the diazo paper with combinations of the above techniques produced several additional conditions. Pre-exposure to LED light removes some percentage of the diazo material from the paper. Coating with one or more of the above reagents can shorten the time for the negative to become completely white. Techniques that have good sharpness and high contrast can potentially be more visually appealing (for example, if a sample changes from 4:2 to 3:1 it would look more like blue on light blue.

Pre-exposure to LED light followed by Chemical treatment

| Pre-exposure | | Time | | | | |
|---|---|---|---|---|---|---|
| time | Treatment | OLED | Sharpness | Contrast | Rate | Notes |
| 1 min LED | None | 5 min | 3 | 5:2 | 1 | Looks similar to untreated |
| | | | | | | with just a slightly lighter |
| | | | | | | negative. |
| 1 min LED | None | 1 min | 2 | 4:3 | >1 | Slightly better than |
| | | | | | | untreated |
| 1 min LED | None | 30 sec | 1 | 5:4 | N/A | Symbol outline barely |
| | | | | | | visible against background |
| 2 min LED | None | 5 min | 3 | 2:1 | >1 | Light blue background but |
| | | | | | | nearly white negative space. |
| 2 min LED | None | 1 min | 2 | 1:1 | >1 | Light blue throughout, little |
| | | | | | | contrast. |
| 1 min LED of | None | 5 min | 3 | 3:1 | >1 | Good blue/white contrast, |
| 1% AIBN | | | | | | though not very sharp. |
| 1 min LED of | None | 1 min | 2 | 2:1 | >1 | Better than non-treated, but |
| 1% AIBN | | | | | | very faint contrast |
| 30 sec LED of | None | 5 min | 3 | 4:1 | >1 | Not as dark as untreated by |
| 1% AIBN | | | | | | good contrast |
| 30 sec LED of | None | 1 min | 2 | 3:2 | >1 | Better than non-treated, but |
| 1% AIBN | | | | | | very faint contrast |
| 1 min LED | 1% AIBN | 5 min | 3 | 4:1 | >1 | Not as dark as untreated by |
| | | | | | | good contrast |
| 1 min LED | 1% AIBN | 1 min | 3 | 3:2 | >1 | Better than non-treated, but |
| | | | | | | very faint contrast |
| 2 min LED | 1% AIBN | 5 min | 3 | 3:1 | >1 | Negative nearly white light |
| | | | | | | blue background |
| 2 min LED | 1% AIBN | 1 min | 3 | 3:2 | >1 | Better than non-treated, but |
| | | | | | | very faint contrast |
| 3 min LED | 1% AIBN | 5 min | 2 | 2:1 | >1 | Negative nearly white light |
| | | | | | | blue background |
| 3 min LED | 1% AIBN | 1 min | | 1:1 | | Nearly completely bleached |
| 2 min LED | 1% AIBN | 1 min | 1 | 2:1 | >1 | Vapor develop with NH4OH |
| | | | | | | does not bring out contrast |
| | | | | | | relative to same conditions |
| | | | | | | and liquid development |
| 2 min LED | 1% AIBN | 1 min | 1 | 2:1 | >1 | Vapor develop with |
| | | | | | | commercial developer does |
| | | | | | | not bring out contrast |
| | | | | | | relative to same conditions |
| | | | | | | and liquid development |
| 2 min LED | 10% AIBN | 5 min | 3 | 3:2 | >1 | Better than non treated, but |
| | | | | | | very faint contrast |
| 2 min LED of | None | 5 min | 3 | 2:1 | >1 | Nearly white, but contrast |
| 10% AIBN | | | | | | visible including symbol. |
| 2 min LED of | None | 1 min | 3 | 3:2 | >1 | Light blue with faint symbol |
| 10% AIBN | | | | | | |

This strategy is effective in achieving a white background in shorter amount of time. Ideally a formulation starting with a lower percent diazo material in the paper or a more reactive diazo material could achieve this goal without need for pre-exposure.

For the above samples, the paper was developed by painting, spraying, or exposing to the vapor of several alkaline materials. These materials included commercial developer (mixture of alkyl amines and solvent), alkyl amines, or ammonium hydroxide. The paper was allowed to dry and the level of blue/white contrast was observed. Ammonium hydroxide was faster at drying, but had little other benefit to the alkyl amines or commercial developer. Development with vaporized ammonium hydroxide or commercial developer are possible and can give decent color, though it was most effective if in a direct stream of vapor rather than exposed to an atmosphere of vapor. Ammonium hydroxide can be vaporized with or without a carrier solvent such as ethylene glycol. Aerosol spraying of the reverse side of the paper continued to be the best method for development.

This work shows that fixing and developing an image on commercial diazo paper can be achieved without the specialized equipment often used in blueprint processes. Exposure to a light source can create an image that is readable given an appropriate level of irradiation to cause the chemical change needed in the paper. Several methods are available for development of the image. Adding light-activated molecules that accelerate the degradation of the diazo compounds and increase the rate of image formation is possible. Many of the above results suggest a more rapid color change and development than versus the control experiments. In particular AIBN and benzoyl peroxide proved superior at this technique, though benzoyl peroxide is not as thermally stable in the long-term. LWUV is by far the most effective light source for fixing an image, but this work has shown that LED and OLED light can be used as well. All tested light sources were able to fix an image on untreated paper given enough exposure time, but treated paper would produce an image of similar quality up to five times faster. Exposure times with the OLED Samsung Galaxy Tablet continue to be greater than 1 minute for good blue/white contrast, though non-treated paper shows low quality images up to 5 minutes of exposure to OLED light. Nonetheless, this improvement is significant.

Reduction in the amount of diazo compound by pre-exposure to LED light was effective in lowering times. This technique could be mimicked by production of novel paper with lower concentrations or more reactive diazo material incorporated into the paper. Development by an alkaline material is essential for the blue color of the diazo paper. It was shown that ammonium hydroxide had advantages over other materials, but commercial non-ammonia developer, alkyl amines, and vaporized developers were effective to some extent. A preferred embodiment would be to formulate new paper with encapsulated amine bases in the formulation that could be heat or pressure released.

Different applications will have individualized processes as each application has unique requirements. Any load can be microencapsulated to yield the desired result. In another example, each sheet of paper is manufactured such that they are manufactured printed in layers with a base of developer encapsulated amine such as DETA, a base diazo and then the overlying grid of CMYK diazo or microencapsulated ink species on X axis and RGB diazo or microencapsulated ink species or CMYK on Y axis and an encapsulated amine developer between each row. In a preferred embodiment, the each sheet of paper is mass produced coated or 3D printed with all of these molecules in associated layers. Each sheet of paper can have as many rows as the pixels array on a smart device display and by knowing which manufacturers' smart device display is being used the paper will be matched. It is being printed from the individual pixels to individual diazo molecules as it will be matched to the paper molecule grid. This yields molecule by molecule diazo burn off and development for complete resolution, background and quality of prints for black and white and color images. The computer controlled printing program will utilize: time, sequence, contrast, brightness control and the grid system, etc. to effectively copy any image directly as it appears on the display screen of the smart device.

With respect to smart device Applets, the main technical challenge of light as the driver in print technology is the current state of the art limited display lumen output. The OLED AND AMOLED screens have the potential to emit enough energy or screen brightness to cause the chemical reactions necessary to reproduce the static image that is onscreen onto the treated substrate so as to create a copy. The computer program or App described herein along with FIG. 4 is believed to be novel as it physically manipulates light interaction with a chemical reaction to generate a given outcome. In one example, the App serves as a “copier” of the displayed image as it converts the displayed image to a black print on a bright background. When the device is “ready to print,” the App increases brightness on the smart device to a highest setting, for example 1100 NIT2. Once the image transfer is complete the App provides an alert (such as a beep) and then a Developer: is applied, which can include an encapsulated and or pressure released encapsulated amine or a bladder and chamber press held for 30 secs and released or continually pumped to circulate. In one example embodiment, the App provides an email option for instant receipt and put it into a predefined App sent file with “who, what, when, where and why” datalog and can be location aware. Where speed is of concern, a high output lumen smart device or a specific Wavelength Display is used to allow true instant printing and to allow the user to utilize all photosensitized materials and associated processes.

In one example embodiment, there is provided for the App to automatically make an image that is brought into the App and is then converted to a black and white image, where black is an off pixel and white is an on pixel and using the brightest background possible the when “print” button or icon is actuated. The increased brightness to as high as possible will assist the image exposure speed. The UVAOLED display for printing will be instant. In various embodiments disclosed herein, the encapsulated amine developer is in or on paper (or other desired substrate). As for colors and x-y grid embodiments, an encapsulated amine is either on every other row or even in a different layer entirely. Examples of encapsulated amines are disclosed in U.S Patent Application Pub. No. 2010/0061897 and U.S. Pat. No. 8,318,060, which are incorporated herein by reference in their entirety.

In an example embodiment related to color printing, different and more effective substrates are generated by mapping the display pixels of specific manufacturers (e.g., Apple, Samsung) to that of the paper or other substrate to be used to capture the image. Individual diazo lines, type of developer and the type, amount and location of the base coating on substrate would be varied for each display format. For example CMYK could be on the horizontal and RGB could be on the vertical or all can be intermixed to have a full coloration of a substrate. As it is mapped to pixels on device, each pixel can be fired as necessary to expose proper position on the x-y axis.

In another related embodiment related to UVAOLED display print and copier aspects, since an OVA (ultraviolet) wavelength of light allows for instant exposure, a smart device can become the copier or a separate device for a standard document size, such as an 8.5×11 UVAOLED display. Slide the treated substrate into a mechanical paper feed while placing the UVAOLED over the substrate and it functions as regular printer. The display is portable and can be taken with you with no information left behind. The mechanical paper feed could also be portable or stand-alone, and the only consumable is the paper (no toner cartridges, nothing to fix or break, etc.). In another example embodiment, the UAVOLED display is used with commercial UV inks could be used.

In related applets to the aforementioned embodiment include but are not limited to, a copier app, a color printing app, a Postal/Shipping app, a 3D imaging app and an app involving activating circuitry printed paper or other substrates. In one example embodiment, the smart display is considered a photon activated electric circuit printing on sensitized substrate such as paper. In this example, Cyanotype and other metallic based photosensitive mixes (and photosensitive printing) are used for photon electronic circuit printing, chipless passive RFID and NFC printing directly onto sensitized substrates and provide low cost, one time use solutions for the user as well. In a related embodiment, the teachings herein provide for interweaving the internet of information with the internet of value and the internet of things, for example; the future of money and finance is the distributed ledger technology developed by Satoshi Nakamoto as expressed in 2008, The Display as Printer Technology disclosed herein is the physical output of distributed ledger technology, such as the bitcoin app to, for example utilize the UVWD printer to “mine” or 3D print bitcoins and/or, for example, use the chemistry described herein and the Display as Printer technology to print 2D (and 3D) such as QR code money wherein a unique identifier generated by a user cannot be replicated therefore eliminating fraud as the system would show any duplication. This form factor would facilitate digital money or would allow for encoded or encrypted printing of physical cash when needed on the chemically treated paper.

In other related embodiments, the photon transfer technology described herein has applications in NFC RFID: asset management, mail fraud and loss prevention; integrated inventory management one cent per unit threshold; and passive RF energized devices. In another application, post and parcel systems can provide: user accounts, labeling, scale weight, optical, jpeg, cloud, passive RFID communication, and display printed digital QR code metering. In another application, printed circuits can be generated from sensitized cyano, silver, copper, aluminum, .etc. metallic, chipless, passive NFC and RFID for use in the internet of things: asset management, consumables, mail, money, etc. In the instance where a proprietary Solution is applied, a display is exposed and the developer is fixed, printing is programmed so as to have display printing, as well as having QR identifiers on documents, NCF and or RFID identifiers on documents. Relatedly, you can always know what is in your briefcase as these identifiers communicate with your smart device or can be used to conduct a quick inventory (as well as the provision of data links). In another application, a QR Code digital stamp can be tied to user account and printed from display. In yet another application, a user can utilize a familiar national regulated currency base paper, as a base for display printed: NFC, RFID, and/or QR code money on the sensitized base or substrate. This would involve display as print technology. Any underlying display technology that can be made to work such as DLP, OLED, AMOLED, Quantum Dots, and other specific wavelength display high precision instruments can be utilized. Of these technologies, those that can be the substrate for the specific wavelength display high precision instrument as described herein will yield the most efficient platform for the printing arts. Examples include the post and parcel system herein described, circuits, RFID, and multiplane printing for additive manufacturing.

In various related embodiments there is provided a method of optimizing the diazo chemistry with precise concentration levels and AlBN for faster exposure times on visible light displays and utilizing pressure released encapsulated ammonium hydroxide or alkyl amines such as DETA for image development. There is also provided a method of optimizing smart device OLED AMOLED Quantum Dot displays brightness settings to speed exposure times and using the UVWD printer for instant diazo copies, fast cyano printing, RFID NFC, and 3D printing with photosensitive polymers. Further, there is provided a method and system of precisely coating, layering, and “printing” the paper with unique CMYK diazo colors and developer in individual rows and in grid patterns to match OEM pixels patterns in displays for high image resolution copies and color copy.

An integrated business process and app for conducting postal and parcel services with a simplified infrastructure using a process for forming or transferring an image from a display onto a substrate without using a legacy printer, labels or physical stamps and using a digital scale and user account connected QR code digital stamp is provided herein.

A method and a system of transferring images and data optically, from one smart device to another device, as well as device display to receiving device over air optical transmission and communication, malware-free and virus-free is provided herein. There is also provided a method of using a smart device display as the “printing surface to directly transfer an image onscreen onto a sensitized substrate and a method of configuring binary on or off with one or more pixels on a smart device display to individually turn on and off and/or to turn on/off in a predetermined sequences substantially simulating a computer version of Morse code.

The Graphite and graphene—In this example embodiment, an amount of graphene or graphite is deposited onto a substrate and assigned a unique ID. Referencing previous discussion on display pixel and photon printing, a USPS envelope can have the QR data rich stamp printed onto the sensitized substrate. The RFID reader will reference the unique ID of the existing graphite RFID tag and link to the unique identifier of the QR stamp file. Now an envelope can be optically read and remotely read via RFID, thus enabling the smart mailbox system to communicate with an end user and enterprise. These are several examples of how the silver methods and graphite methods will help make the internet of things a low cost reality.

Another example of the system's value is in product lifecycle or end to end asset management, recycling of pop bottles other plastics, etc., can new be remotely read by machine and routed to the proper location for reuse. This offers vast opportunities to reduce recycling costs and creates a seamless method for reclamation of goods. Graphite and graphene offer substantial electrical properties that are low cost means to enable low cost universal tagging for the internet of things. The advantages are many. Graphite is cheap, thus we can achieve the sub 1 penny mark for item tagging. The graphite or graphene is deposited onto packaging such as USPS envelopes, inventory, goods, items, materials. The graphite can be doped with copper, aluminum or other conductive materials to create electrical signature variances that can be used as both the antennae and the unique identity. The shape of the print and or the use of additional metals make the physical graphite act as both the ID and the antennae. In a related experiment, silver alginate was tested and determined to be formable to be: 1) conductive and 2) low cost 3) fast so that the App could code and print unique RFID tags as it printed the rest of the info onto mail. Normally, the silvers are too expensive, slow and hard to conduct as per attached report. The graphite, graphene and readily available conducive inks are far superior but lack photosensitive attributes, therefore to address this, the photosensitive envelopes will be preprinted with a passive chipless RFID tag in the form of the graphite or conductive glue which are formed in an antennae design such as a unique snowflake design and as such be pre coded. As the envelope is addressed and the stamp is printed, the QR code and RFID will be linked as per the flowchart. Another method is to microencapsulate the loads such as the graphite or other conductive material and deposit it onto envelopes. When all of the information (such as sender, receiver, weight and postage) is inputted into the system, the display will rupture the microencapsulated graphite or other loads into an RFID tag unique identifier.

Passive RFID tags and photon printed: RFID tags and circuit printing 2 methodologies for low cost display transferred instant circuits and RFID tags: Circuits and RFID and Near Field tags are expensive to make, wasteful of materials etc. It would be advantageous, as described here in for a methodology that allows circuits to be deposited or printed directly to a substrate, anytime anywhere. It would be advantageous to use the smart device display as the printer to transfer the image or circuit design onscreen directly to the photosensitive substrate as previously described in my patent pending application. It would be advantageous to also have a low cost method of circuit making or having RFID tags already placed on for example packaging such as USPS envelopes that already have unique identity and that can be linked to an existing barcode, QR code etc. Passive, chipless graphite RFID tags can also be used for low cost beginning to end use throughout any supply chain for asset management and internet of things. For example, a computer part, or a one-time use bottle can now be linked throughout the object's lifetime of manufacture to recycling. The data fields can merely be a class code and material type, such as the bottle, or data rich such as a piece of mail, or a computer part composed of many materials.

In another embodiment, the teachings herein are used directly using a device display face as the printing surface. The photons transfer the image from the display directly onto the photosensitive substrate: in this example, two photosensitive metallic methods will be used to print a circuit directly onto a sensitized substrate: Albumen printing processes; Silver alginate: U.S. Pat. No. 3,227,553. These coatings can be applied as needed, pre-coated, etc. Upon exposure to UV light emitted from the display, the image of the circuit that is onscreen will transfer to the substrate.

In one example embodiment, there is provided a method of generating an image on to a substrate by transferring an image from a display onto the substrate including the steps of providing a substrate with a composite coating thereon, the composite coating comprised of an photosensitive image capturing element and a developer element and an image stabilizer and selecting an image for transfer from the display and reversing the selected image to form a reversed image. The reversed image is projected from the display to the substrate with energy emitted from the display and then the transferred image is developed on the substrate by using energy to release the developer element within the composite coating so as to react with the image capturing element. In a related embodiment, the image capturing element includes a diazo-based chemical species sensitive to light and the developer element includes a pressure-released microencapsulated amine selected from the group consisting of ammonium hydroxide, alkyl amines and triamines such as DETA. In this embodiment, the diazo-based chemical is combined with a reagent to speed up diazo exposure times, the reagent selected from the group consisting of ethanol, azobisisobutyronitrile (AIBN), Benzoyl Peroxide (BP), Riboflavin (RIBO), Ru(BPY)₃Cl₂ (RUBPY), and potassium antimony tartarate (TE). In a related embodiment, the energy used to release the developer element within the composite coating is selected from the group consisting of mechanical release, ultrasonic energy waves and infrared energy waves. The energy used to release the developer element within the composite coating can also include a mechanical force across a surface of the coating to release the developer element.

In a related embodiment, the microencapsulation of materials is also another mechanism for the delivery of various loads that generates another method of single or multidimensional printing. With this approach true and instant color copies or photos can also be generated on a substrate without the use of legacy style printer. By way of example, the mapping system disclosed herein of 2D and 3D manufacturing of paper and/or coatings can lay the microencapsulation compound row by row, layer by layer on an X, Y, Z axis/direction (building it up as in a 3D structure) on the substrate such as paper. CMYK RGB color, for example, can be mapped to pixel grid of a given device and then the shells can be ruptured by a specific UVA wavelength such as 365 nm. A software controlled program is then used to release the desired ink or load by turning on the equivalent pixel to rupture the microencapsulated shell.

In another related embodiment, instant printing is also achievable for RFID and printed circuits on non-traditional substrates using an approach similar to the above described method. In this example embodiment, a conductive glue (such as a graphite or some type of metal) is deposited on a substrate (such as paper), which is deposited in the same manner as described above, by layer and by row by row in an X, Y, Z axis/direction, such that the polymers act as insulators (unruptured) and the ruptured shells allow the circuits and antennas to be any shape desired. The specific wavelength display printer used in this application is configured to have several wavelengths including, for example, 400 nm to be used for amine release, and 365 nm for ink and graphite release. In this manner all imaging technologies and compounds, such as diazo based, ink and carbon based can be on one substrate, if desired, or if inks or carbon present need to be cured, a specific wavelength can be used to perform this function. Therefore, for example, an envelope could have diazo with microencapsulated developer in the necessary specific label areas (addressee, addressor, and postage area) for development. The graphite microencapsulation could be where the existing “snowflake” tag or image resides.

In a related embodiment, the display for the image generating method is selected from the group consisting of a display, a non-backlit LED, an OLED display, an AMOLED display and a Quantum Dot display. In this example embodiment, the display is a specific wavelength display configured to be used as a printer and the composite coating is configured for instant 2D cyano and diazo printing and wherein the composite coating is configured with any one of photosensitive polymers, metals and conductive materials for 3D printing. In a related embodiment of generating an image, the step of providing the coated substrate includes the step of layering on paper as the substrate with a predefined CMYK diazo colors and developer composite coating in individual row and in grid patterns to match pixel patterns in the display to improve image resolution and represent colors of a multicolored image transfer.

In yet another related embodiment, the image generating method is configured for use in connection with a postal and parcel delivery service, wherein the transferred image is a postage symbol and the substrate receiving the transferred image is an item to be shipped or a shipping label. The method further comprises the step of using a digital scale for weighing the shipped item and selecting a second image for transfer unto the shipped item or shipping label comprised of a user purchased QR code digital stamp. In a related embodiment, the method further comprises the step of forming an image on the shipped item or label selected from the group consisting of an RFID tag, an NFC code, and a bar code.

In another example embodiment, a system is provided for generating an image onto a substrate by transferring an image from a display onto the substrate, the system including a substrate with a composite coating thereon, the composite coating comprised of a photosensitive image capturing element and a developer element. The system includes a smart device comprising a display, a microprocessor and memory and a power source, the smart device including a software program configured to allow a user to select an viewable image for transfer from the display onto the substrate, the software program further configured to convert the selected viewable image to a reversed image version of the selected image, wherein the software program initiates projecting the reversed image of the selected image from the display to the substrate with energy. The system includes also a mechanism for developing the transferred image on the substrate using energy to release the developer element within the composite coating so as to react with the image capturing element.

In a related embodiment, there is provided a device comprising a display, a microprocessor and memory and a power source, the device including a microprocessor enabled software program configured to allow a user to select an viewable image for transfer from the display, wherein the software program initiates projecting the selected image from the display towards another object with energy for a predetermined period of time. The software program is further configured to convert the selected viewable image to a reversed image of the selected image, the software program initiating the projection of the reversed image of the selected image from the display towards another object with energy for the predetermined period of time. In a related embodiment, the device is configured for transferring images and data optically from the smart device to a receiving device over air optical transmission and communication, malware-free and virus-free. In this embodiment, data is communicated between the devices via a pixel on/pixel off action and a color language in a sequence received by the receiving device. In a related embodiment, the device is configured for binary on or off communication with one or more pixels on the smart device display to individually turn on and off and/or to turn on/off in predetermined sequences substantially simulating a computer version of Morse code.

In yet another example embodiment, a system is provided for generating an image onto a substrate by transferring an image from the display onto the substrate, the system including a substrate with a composite coating thereon, the composite coating comprised of an photosensitive image capturing element and a developer element, wherein the software program of the display device initiates projecting the reversed image of the selected image from the display towards the substrate with energy. The system also includes a mechanism for developing the transferred image on the substrate using energy to release the developer element within the composite coating so as to react with the image capturing element. In a related embodiment, the composite coated substrate is formed from layering on paper as the substrate with a predefined CMYK diazo colors and developer composite coating in individual row and in grid patterns to match pixel patterns in the display to improve image resolution and color of the image transfer.

The use of microencapsulated materials has been described in reference to 2D-printing applications of the present invention, and these materials may also be useful for some multi-plane (3D) additive manufacturing applications of the present invention. Microencapsulation is an existing technology that uses, for example, polymers, lipids and other materials to enclose solids, liquids, gases or combinations thereof on a micron scale. These very small particles or liquid droplets that are placed within spherical shells to form microscopic capsules. The outer shells are commonly called “walls” and the inner fill materials are commonly called “loads.” The micro capsules that may be used in various applications of the present invention may cover a wide range of sizes but are typically smaller than 100 microns because the smaller the capsule, the higher the resolution. Traditionally, microencapsulation as it is used in connection with print technology involves processing by mechanical release, such as drawing a pen across NCR (no carbon required) paper to release the load necessary to make a copy effectively. With specific wavelength display high precision instruments, a new processing method is created via specific wavelength processing of the microencapsulation material itself. Further, specific wavelength display is a new means of processing load materials such as specific wavelength display melting, drying, curing, sintering and so forth. This changes the existing art of mechanical release to that of multi-functional, multi-material, non-mechanical means at a micron level for high precision applications. In this manner, a new delivery method is created to allow non-photosensitive materials to be utilized with display as print technology. For example, a non-photosensitive conductive material such as low cost graphite can be mixed with a photosensitized carrier conductive paste as a load material that can then be further processed upon release.

As previously described, the microencapsulated loads may be comprised of a wide range of materials including photosensitive inks and graphite particles dispersed in electrically conductive and photosensitive liquids. As an example of an application of the present invention that prints “smart” envelopes, an envelope may have a layer of microencapsulated ink bonded to a first area of the envelope surface, and a layer of microencapsulated graphite/conductive paste compound bonded to a second area of the envelope. The envelope may then be exposed to a first specific wavelength of radiation in a specific image pattern that bursts a portion of the micro capsules containing ink, thereby applying wet ink in the shape of the mailing address to the first area of the surface of the envelope. A second burst of radiation at a second wavelength may then be used to cure the ink and bond it to the surface of the envelope. A third burst of radiation at a third wavelength in a specific image pattern may then be used to burst a portion of the microcapsules containing the graphite/conductive paste compound, thereby forming a pattern of electrically conductive traces on the second area of the surface of the envelope, and these traces may be in the form of an RFID circuit that can be used to identify and track the envelope during the delivery process. A fourth burst of radiation at a fourth specific wavelength may be used to cure and bond the conductive traces to the surface of the envelope.

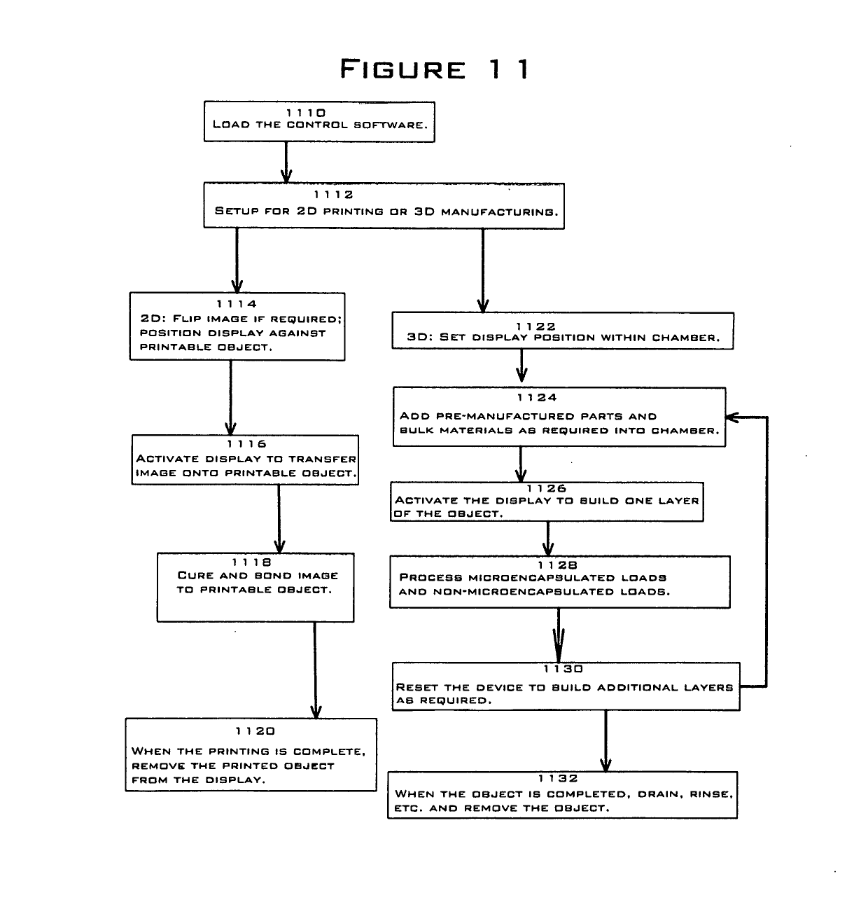

When microencapsulated materials are used in 3D manufacturing applications of the present invention, the microencapsulated materials are precisely extruded onto the object being manufactured via catheters, as described in reference to FIGS. 11, 12 and 28. An example of the use of microencapsulated materials for construction of a 3D object is as follows: a powder, slurry or liquid comprised of low-cost graphite/conductive paste microcapsules that are dispersed in a liquid is extruded via a first catheter onto the surface of the object being printed (or from origin, if the object does not yet exist). A second catheter follows behind the first catheter and emits radiation at a certain first wavelength via an LED mounted on the tip. The radiation process bursts the walls of the micro capsules, thereby allowing the graphite/conductive paste mixture to contact the surface of the object. The second catheter then emits radiation at a certain second wavelength that cures the graphite/conductive paste mixture and bonds it to the surface of the object, thereby forming an electrically conductive trace. The shape and physical position of the trace is precisely controlled by a computer which guides the two catheters. A single catheter could also be comprised of delivery of materials and have an incorporated set of emitters to allow one-pass deposition and processing to further speed manufacturing.

The procedure described in the previous paragraph for constructing an electrical trace may also be used with non-microencapsulated materials. For example, a graphite/conductive paste mixture that is not in encapsulated form may be extruded directly from a first catheter onto the surface of an object (or from original, if the object does not yet exist), and may then be cured and bonded to the surface of the object by radiation emitted from a second catheter.

FIG. 11 is a flowchart that illustrates the multiple steps involved in the 2D printing and 3D additive manufacturing processes of a single-plane, single display application of the present invention. The processes described in FIG. 11 are compatible with display devices such as cellular “smart” phones or similar single-screen devices. Referring to Step 1110 of FIG. 11, the internal computer of the display device is programmed with a digital description of an object to be printed or manufactured, plus appropriate control software to activate the pixels of the display screen as required to print or manufacture the object. In Step 1112, the display device is set up as required, depending on whether 2D printing or 3D manufacturing is desired. If 2D printing is required, for example to address and stamp an envelope, then Step 1114 makes a mirror image (“flipped image”) of the display image, if required, and the display screen is placed in contact with a printable object, such as a blank envelope having a photosensitive surface (for example, a surface coated with one or more layers of microencapsulated material). In Step 1116, the display is activated, and the displayed image is transferred to the printable object by emission of a specific wavelength of light (for example, as described above, by bursting the walls of a portion of the micro capsules with radiation having a first specific wavelength, thereby releasing the microencapsulated loads of ink from the burst capsules.). In Step 1118, the display image is bonded to the printable object (for example, by emitting radiation having a second specific wavelength, which cures the ink and bonds it to the surface of the printable object). In Step 1120, when the image transfer is complete, the printed object is removed from physical contact with the display screen. Referring back to Step 1112, if additive manufacturing of a 3D object is desired, then Step 1122 is implemented, wherein the display device(s) form a chamber or are is installed into a manufacturing chamber and appropriately positioned. In Step 1124, the chamber is loaded with pre-manufactured parts (such as batteries) and uncured resin. In Step 1126, the display is activated so that material in contact with the active pixels of the display is cured by emission of radiated light from the display, thereby forming the first layer of the manufactured object. In Step 1128, processing of microencapsulated loads and non-microencapsulated loads into objects such as printed circuit boards is accomplished, if required. As described above, processing of microencapsulated loads typically comprises the steps of 1) extruding a slurry of micro capsules and liquid onto a previously manufactured layer via a first catheter; 2) bursting the walls of the capsules with a first specific wavelength of radiation from a second catheter, thereby releasing the loads from the shells; and 3) curing and bonding the loads to the previously manufactured layer with a second specific wavelength of radiation from the second catheter. The processing of non-microencapsulated loads typically comprises the following steps: 1) extruding a desired liquid (for example, a graphite/paste mixture) onto a previously manufactured layer via a first catheter; and 2) curing and bonding the extruded liquid onto the previously manufactured layer with a specific wavelength of radiation from a second catheter. In Step 1130, the completed layer is pulled away from the display screen, and then Steps 1124 through 1130 are sequentially repeated as required until the all of the layers of the manufactured object have been completed. In Step 1132, when the object has been completed, final operations such as draining the chamber and rinsing the manufactured object are performed.

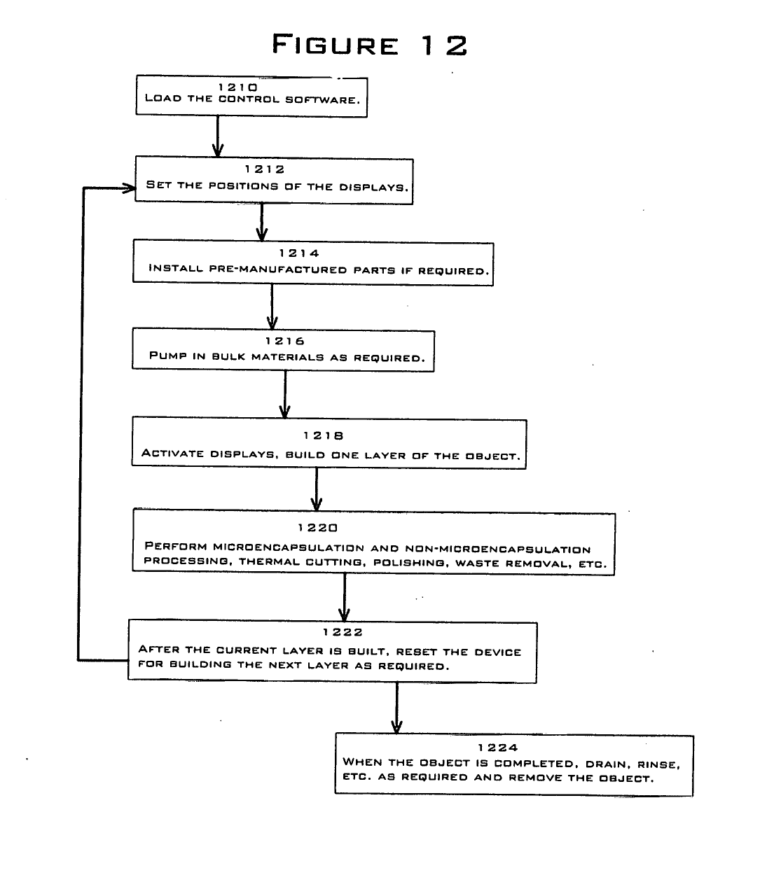

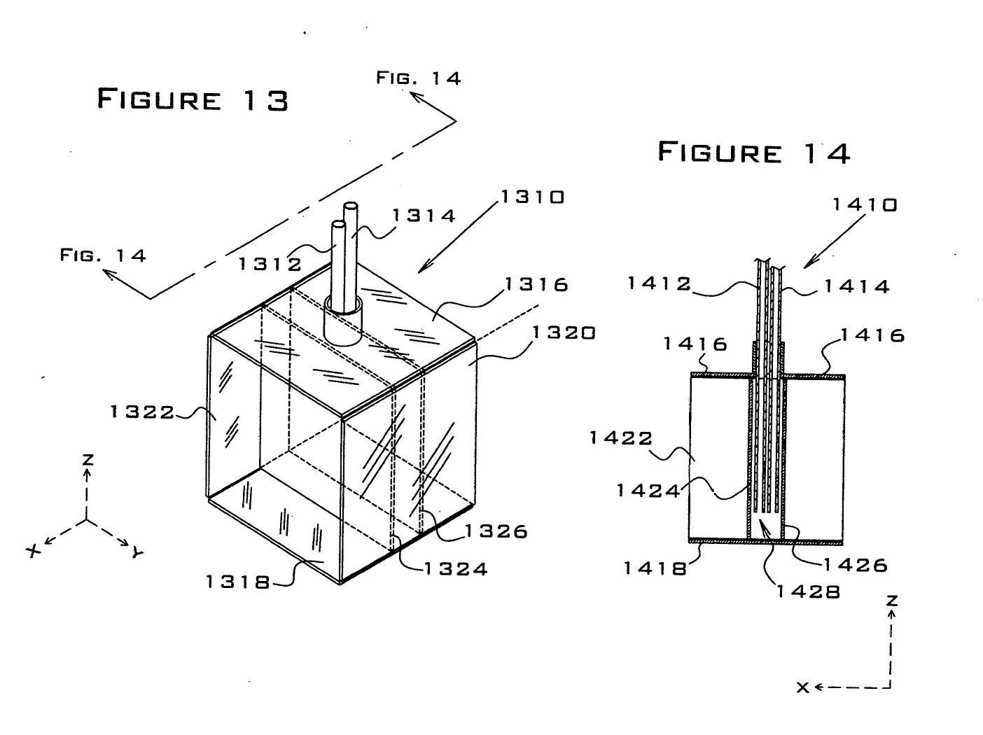

FIG. 12 is a flowchart that illustrates the multiple steps involved in the additive manufacturing process of a manufacturing device comprising the multi-plane, multiple unit displays of the present invention, such as the multi-plane display applications of the present invention shown in the following FIGS. 13 through 27. Applications that comprise multi-plane, multiple unit displays are particularly well suited for the additive manufacture of 3D objects. Major components of multi-plane, multiple unit display manufacturing devices include the displays, an internal chamber (formed by the displays), delivery tubes and optional catheters. Referring to FIG. 12, in Step 1210, control software is loaded into a process control computer. The control software provides computer instructions for manufacturing a particular object, which may be a complex object (for example, a cellular telephone). Functions of the control software include setting the physical positions of the displays and storing in memory the computer code that defines the images to be output on the displays, inserting bulk materials such as uncured resin when required, and controlling the positions and outputs of the catheters. In Step 1212, the positions of each of the displays are set along the X, Y and Z axes of the manufacturing device in preparation for printing a single layer of the object being manufactured. In Step 1214, pre-manufactured subsystems of the manufactured object (such as integrated circuit chips, batteries, etc.) are precisely positioned within the chamber of the manufacturing device as required, for example, as components of a cellular telephone that is being manufactured by the device, as explained below. In Step 1216, bulk materials (such as uncured photosensitive resin) are pumped via delivery tubes into the chamber of the manufacturing device. These bulk materials come into direct contact with at least some of the displays and provide the predominate materials for the manufactured object. In Step 1218, one or more of the displays are activated so as to output a digital image. The bulk material that is in contact with an activated display is thereby selectively cured by one or more specific wavelengths of radiation (typically ranging from ten nanometers to one meter) emitted from the display to form one layer of the manufactured object that corresponds to the shape of the image being displayed. In Step 1220, special manufacturing processes are performed by one or more catheters and optionally, one or more displays. These special manufacturing processes include (but are not limited to) processing of microencapsulated loads and non-microencapsulated loads as described previously in reference to FIG. 11, temporary masking of selected zones followed by removal of the masking in a following step, thermal cutting of conductive traces, polishing of specific areas of the object, and withdrawal by suction of waste material. Microencapsulated and non-microencapsulated load materials may include, but are not limited to, graphite, conductive inks, dyes, polymers, metals including silver and gold, and biological materials. A combination of different wavelengths of radiation may be used to selectively cure different materials. Objects that may be manufactured via load processing by microencapsulation and non-microencapsulation include, but are not limited to, printed circuit boards (PCBs), electronic circuits such as RFIDs and antennas. In Step 1222, the manufacturing device is reset to perform the next series of manufacturing steps (i.e., repeat Steps 1212 through 1222), which comprise resetting the display positions for the next layer to be manufactured, inserting pre-manufactured subsystems if required, pumping in additional bulk material if required, activating one or more displays to form the next layer of the manufactured object, and performing specialized manufacturing operations, if required. The manufactured object may remain in a stationary position within the chamber during the manufacturing process, or alternately, it may be repositioned and rotated between manufacturing steps, if such movement is beneficial to the manufacturing process. (Conventional wet bath 3D printers utilize non-moveable or single-plane moveable print heads, and the manufactured object is typically mechanically raised up through the chamber as each layer is formed.) In Step 1224, when all of the manufacturing steps have been completed, the chamber may be drained, and the manufactured object may be rinsed, coated, or otherwise treated and then removed from the chamber.

Using a cellular telephone as an example of a device that could be produced using the multi-plane, multiple display technology of the present invention in accordance with the flowchart shown in FIG. 12, the manufacturing steps would be as follows: Step 1210, load the control software; Step 1212, set the displays to print the first layer, which could be from origin (as in printing from the inside out) or begin at an outside surface of the case of the cellular telephone. Cycle through Steps 1214 through 1222 to build the telephone case from resin with the displays, insert pre-manufactured integrated circuits, use catheters to manufacture objects such as printed circuit boards, connecting wires, antenna, etc., insert display face glass and, finally, polish and rinse the final product as required.

FIGS. 13 through 27 illustrate various example applications of the 3D display-as-print technology of the present invention as described previously and shown in flowchart form in FIG. 12. Each of the examples shown in FIGS. 13 through 27 comprises a plurality of displays, with at least some of the displays being capable of movement as images are being transferred from the displays onto a photosensitive substrate within an internal chamber. In general, the displays of each example application are initially positioned to provide a minimal internal volume that is just large enough to allow printing of the first layer of the object to be printed, but other starting positions of the displays may be utilized. The displays may be individually adjusted as required between the printing of each layer to provide direct contact of one or more displays with the object being printed. The mechanical and electrical components that provide the adjustments for the various displays are not shown in FIGS. 13 through 27.

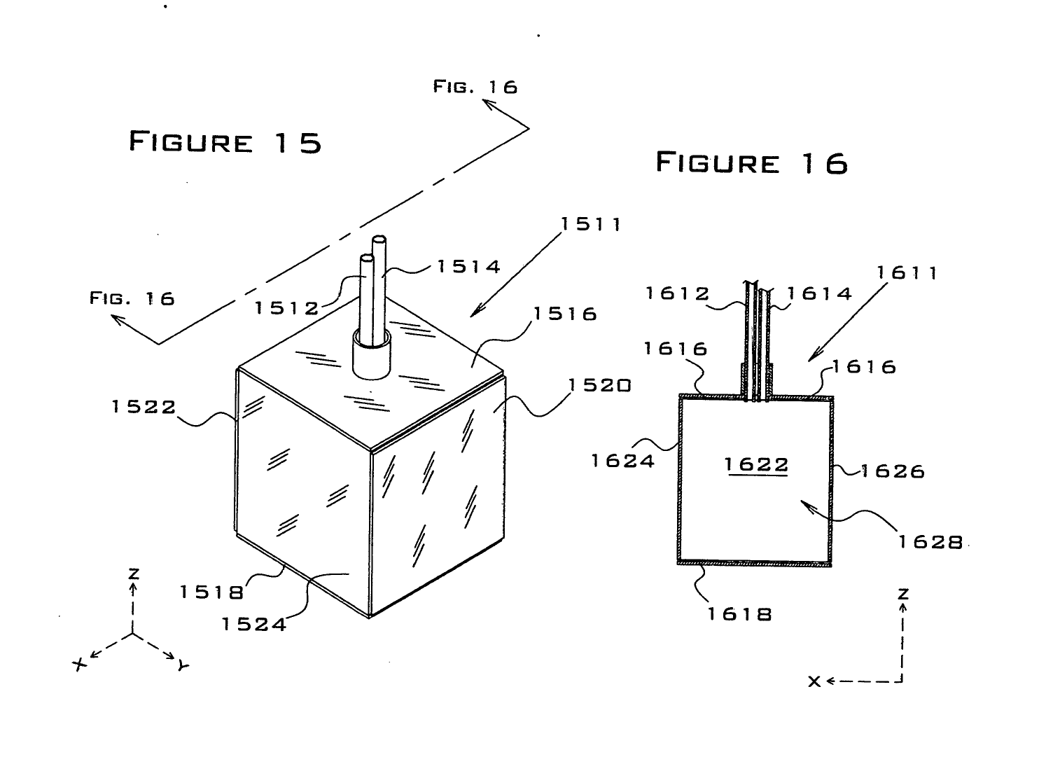

FIGS. 13 through 16 illustrate the displays of the first example application of the present invention, which is a six-sided, rectangular (i.e., parallelepiped-shaped) printer having a left display and a right display that are positionally adjustable, and having a top display, bottom display, front display and rear display that are positionally fixed. FIGS. 13 and 14 illustrate the first example application with the left and right displays adjusted to provide minimal volume of the internal chamber of the invention, while FIGS. 15 and 16 illustrate the first example application with the left and right sides adjusted to provide maximal volume of the internal chamber of the invention. FIG. 13 is an isometric view of the first example application with minimal internal chamber volume 1310 showing a first delivery tube 1312 and a second delivery tube 1314 extending through the top display 1316 of the first example application 1310. The delivery tubes 1312, 1314 are used to convey resin or other raw printing materials into the printing chamber of the device, and are common to all example applications of the invention. In the first example application, the top display 1316, the bottom display 1318, the front display 1320 and the rear display 1322 are fixed in position, while the left display 1324 and the right display 1326 are capable of movement along the X axis but are fixed with respect to the Y and Z axes (as defined by the XYZ coordinate axes shown). The top display 1316 may be removed as required to insert or remove objects from the device before, during or after a printing operation. A removeable display feature is common to all example applications of the invention.

FIG. 14 is a cross-section view of the first example application with minimal internal chamber volume 1410, with the section line taken as shown in FIG. 13. As shown in FIG. 14, the left display 1424 and the right display 1426 are each positioned so as to result in an internal chamber having a minimal volume 1428. The volume of the internal chamber having a minimal volume 1428 may be increased by moving the left display 1424 along the X axis in the left direction, or by moving the right display 1426 along the X axis in the right direction, or by simultaneously moving the left display 1424 in the left direction along the X axis and moving the right display 1426 in the right direction along the X axis (as defined by the XZ coordinate axes shown). Also shown are the first and second delivery tubes 1412 and 1414, the bottom display 1418, the top display 1416 and the rear display 1422.

FIG. 15 is an isometric view of the first example application with maximal internal volume 1511 showing the first delivery tube 1512, the second delivery tube 1514, the top display 1516, the bottom display 1518, the front display 1520, and the rear display 1522 with all these displays in the same positions as shown in FIG. 13, but with the left display 1524 moved in the left direction along the X axis to its leftmost allowable position. In this configuration, the right display (not visible in FIG. 15) has been moved to the rightmost allowable position along the X axis.

FIG. 16 is a cross-section view of the first example application with maximal internal chamber volume 1611, with the section line taken as shown in FIG. 15. As shown, the left display 1624 is positioned at its leftmost allowable position along the X axis, and the right display 1626 is positioned at its rightmost allowable position along the X axis, thereby resulting in an internal chamber having a maximized volume 1628. Also shown are the first and second delivery tubes 1612 and 1614, the top display 1616, the bottom display 1618 and the rear display 1622.

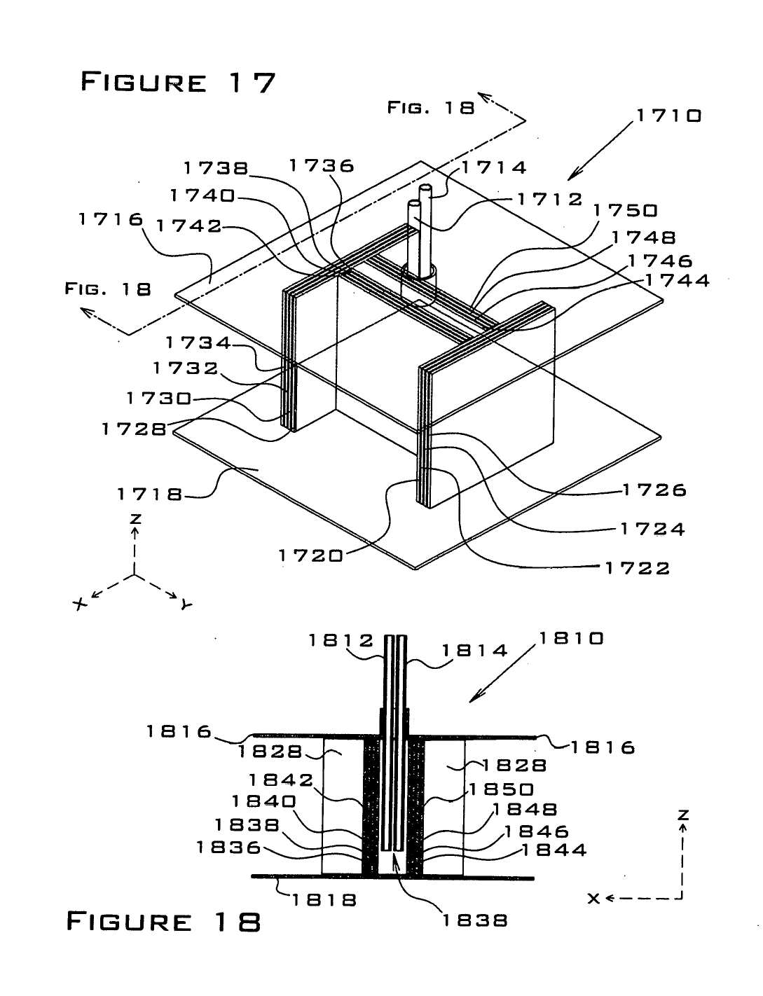

FIG. 17 is an isometric view of the second example application of the present invention, which is a parallelepiped-shaped printer that comprises one top display and one bottom display, and four displays each for the front, rear, left and right sides, shown with the internal chamber in a minimal volume position. In this configuration, the bottom display 1718 has a fixed position, the top display 1716 is moveable along the Z axis only, the first through fourth front displays 1720, 1722, 1724 and 1726 are moveable along the X, Y, and Z axes, the first through fourth rear displays 1728, 1730, 1732 and 1734 are moveable along the X, Y, and Z axes, the first through fourth left displays 1736, 1738, 1740 and 1742 are moveable along the X, Y, and Z axes, and the first through fourth right displays 1744, 1746, 1748 and 1750 are moveable along the X, Y, and Z axes (as defined by the XYZ coordinate axes shown).

FIG. 18 is a cross-section view of the second example application, shown with the internal chamber in a minimal volume position 1810, with the section line taken as shown in FIG. 17. As shown, the first through fourth left displays 1836, 1838, 1840 and 1842 are positioned at their rightmost allowable positions, while the first through fourth right displays 1844, 1846, 1848 and 1850 are positioned at the leftmost allowable positions, thereby resulting in an internal chamber having a minimal volume 1838. Also shown are the first and second delivery tubes 1812 and 1814, the top display 1816, the bottom display 1818 and the first rear display 1828.

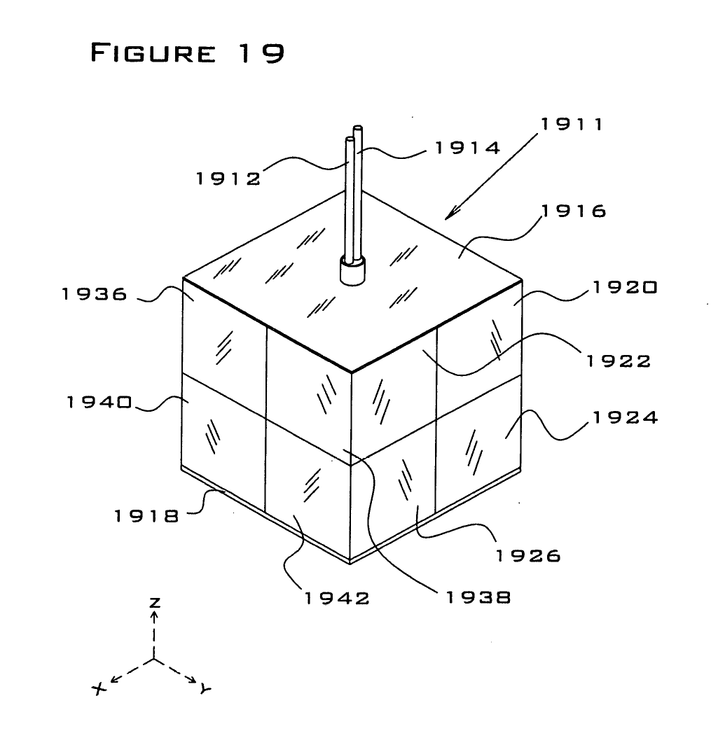

FIG. 19 is an isometric view of the second example application, shown with all of the displays positioned to as to provide an internal chamber having a maximal internal volume 1911. As compared to FIG. 17, the bottom display 1918 has remained in the same fixed position, while the top display 1916 has moved upward along the Z axis, the first through fourth front displays 1920, 1922, 1924 and 1926 have moved outward from the center of the invention along the X, Y and Z axes, and the first through fourth left displays 1936, 1938, 1949 and 1942 have moved outward from the center of the invention along the X, Y and Z axes. In addition, in this maximal volume position of the internal chamber, the first through fourth rear displays and the first through fourth right displays (not visible in FIG. 19) have also moved outward from the center of the invention along the X, Y and Z axes. Also shown are the first and second delivery tubes 1912 and 1914.

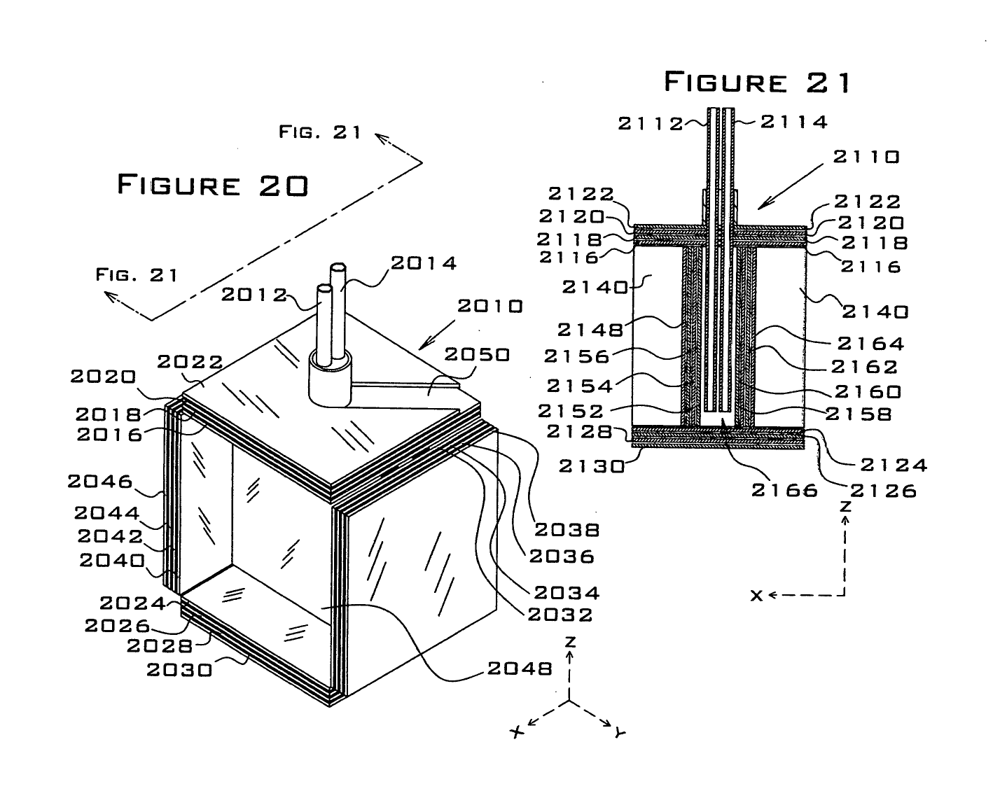

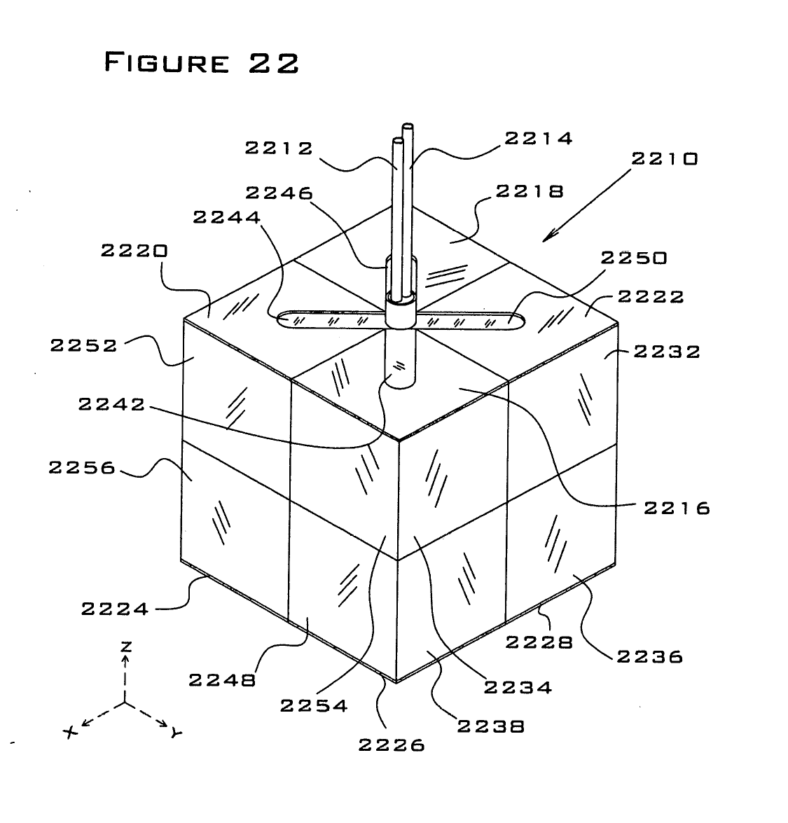

FIG. 20 is an isometric view of the third example application of the present invention, which is a parallelepiped-shaped printer that comprises four displays each for the top, bottom, front, rear, left and right sides, shown with the internal chamber in a minimal volume position 2010. FIG. 20 shows the first and second delivery tubes 2012 and 2014, the first through fourth top displays 2016, 2018, 2020, 2022; the first through fourth bottom displays 2024, 2026, 2028 and 2030; the first through fourth front displays 2032, 2034, 2036, 2038; the first through fourth rear displays 2040, 2042, 2044, 2046; and the fourth left display 2048. In this configuration, all of the twenty-four displays are moveable along the X, Y and Z axes, as shown in FIG. 22. The cutout channel in the fourth top display 2050 allows the fourth top display 2022 to be repositioned without disturbing the positions of the first and second delivery tubes 2012 and 2014.

FIG. 21 is a cross-section view of the third example application, shown with the internal chamber in a minimal volume position 2110, with the section line as shown in FIG. 20. As shown, the first through fourth left displays 2152, 2154, 2156 and 2148 are positioned at their rightmost allowable positions, while the first through fourth right displays 2158, 2160, 2162 and 2164 are positioned at their leftmost allowable positions, thereby resulting in an internal chamber having a minimal volume 2166. Also shown are the first and second delivery tubes 2112 and 2114, the first through fourth top displays 2116, 2118, 2120 and 2122 and the first through fourth bottom displays 2124, 2126, 2128 and 2130.

FIG. 22 is an isometric view of the third example application, shown with all of the displays positioned so as to provide an internal chamber having a maximal volume. As compared to FIG. 20, all of the twenty four displays have moved outward from the center of the invention along the X, Y and Z axes. The cutout channels 2242, 2244, 2246 and 2250 in the first through fourth top displays 2216, 2218, 2220 and 2222 allow the top displays 2216, 2218, 2220 and 2222 to be repositioned without disturbing the positions of the first and second delivery tubes 2212 and 2214. Also shown are the first through fourth front displays 2232, 2234, 2236 and 2238, and the first through fourth left displays 2250, 2252, 2254 and 2248.

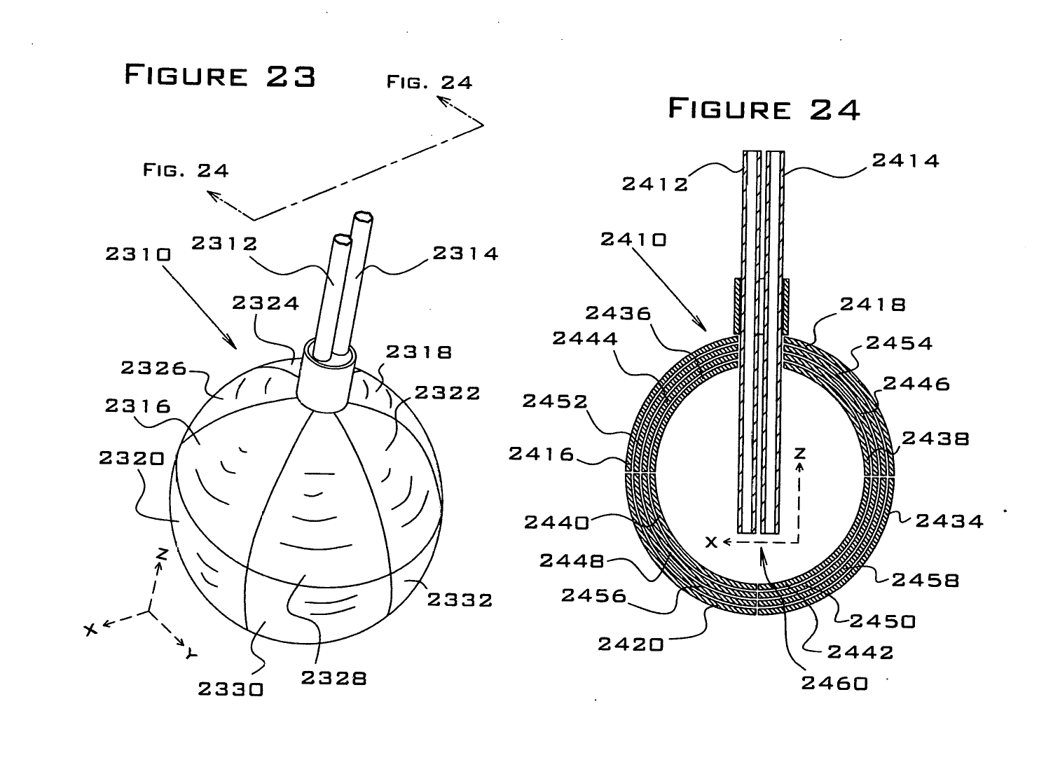

FIG. 23 is a perspective view of the fourth example application of the present invention, which is a spherically shaped printer, shown with the internal chamber in a minimal volume position 2310. When in this minimal volume configuration, the fourth example application comprises four layers of displays, with twelve displays per layer. FIG. 23 shows the first through ninth displays of the fourth (outermost) layer 2316, 2318, 2320, 2322, 2324, 2326, 2328, 2330 and 2332.

FIG. 24 is a cross-section view of the fourth example application, shown with the internal chamber in a minimal volume position 2410, with the section line as shown in FIG. 23. As shown, the four layers of displays are concentrically positioned, with the first layer of displays being the innermost layer, the second layer of displays being outside of the first layer, the third layer of displays being outside the second layer, and the fourth (outermost) layer being outside of the third layer. Shown in FIG. 24 are the first through fourth displays of the first layer 2436, 2438, 2440 and 2442; the first through fourth displays of the second layer 2444, 2446, 2448 and 2450; the first through fourth displays of the third layer 2452, 2454, 2456 and 2458; and the first, second, third and tenth displays of the fourth layer 2416, 2418, 2420 and 2434.

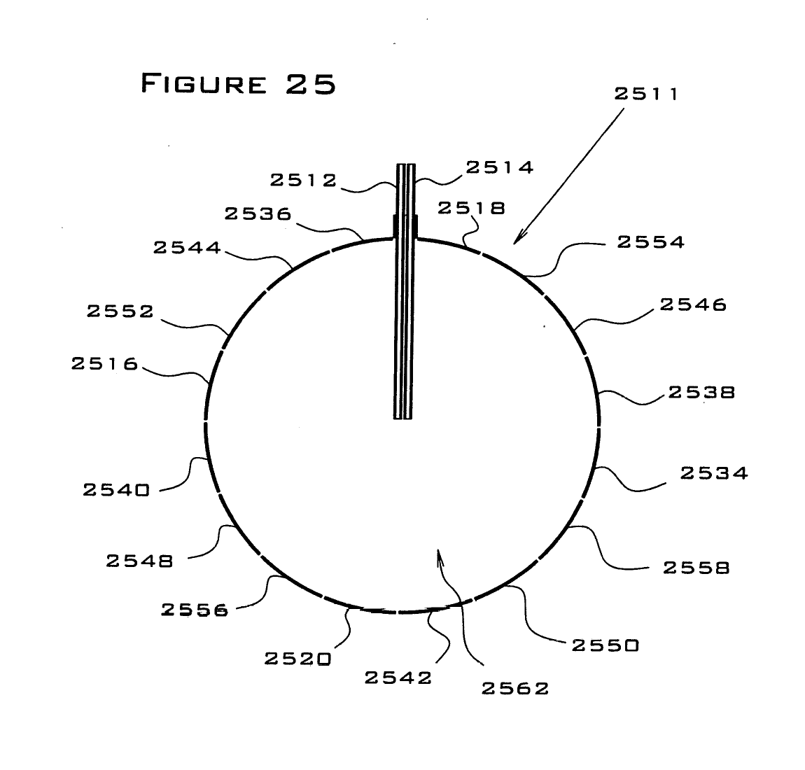

FIG. 25 is a cross-section view of the fourth example application, shown with maximal internal chamber volume 2511. FIG. 25 is similar to the view of the fourth example application shown in FIG. 24, except that in FIG. 25, the displays have been repositioned by moving all of the displays to their furthermost allowable position away from the center of the invention. In this configuration, the displays forming four concentric layers as shown in FIG. 24 have been repositioned to form a one-layer spherical surface, thereby creating an internal chamber having a maximal volume 2562. The displays shown in FIGS. 24 and 25 have sufficient flexibility so that their curvature may be adjusted as they are repositioned.

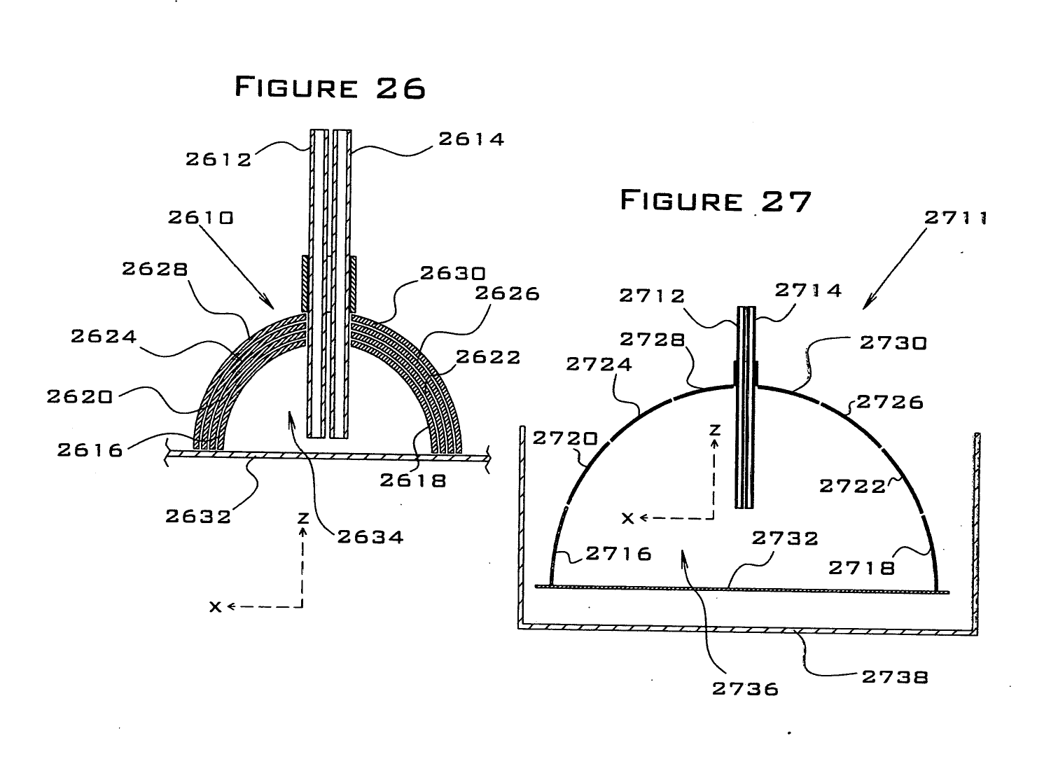

FIG. 26 is a cross-section view of the fifth example application of the present invention, which comprises a hemispherical top and a flat bottom, shown with the internal chamber in a minimal volume position 2610. This configuration comprises four layers of hemispherical top displays with six displays per layer, and a single bottom display. The four layers of top displays are positioned concentrically, with the first layer being the innermost layer, with the second layer outside the first layer, the third layer outside the second layer, and the fourth (outermost) layer outside the third layer. Each of the displays in the hemispherical section is moveable along the X, Y and Z axes, while the bottom display has a fixed position. Shown in FIG. 26 are the first and second displays of the first layer 2616 and 2618, the first and second displays of the second layer 2620 and 2622, the first and second displays of the third layer 2624 and 2626, the first and second displays of the fourth layer 2628 and 2630, and the bottom display 2632. The first and second delivery tubes 2612 and 2614, and the internal chamber with minimal volume 2634 are also shown.

FIG. 27 is a cross-section view of the fifth example application with maximized internal chamber volume 2711 that is similar to the view of the fifth example application shown in FIG. 26, except that the displays have been repositioned by moving all of the top displays to the furthermost allowable position away from the center of the invention, while keeping the position of the bottom display fixed. In this configuration, the top displays forming four concentric layers as shown in FIG. 26 have been repositioned to form a one-layer hemispherical surface, thereby creating an internal chamber having a maximal volume 2736. Shown in FIG. 27 are the first and second displays of the first layer 2716 and 2718, the first and second displays of the second layer 2720 and 2722, the first and second displays of the third layer 2724 and 2726, the first and second displays of the fourth layer 2728 and 2730, and the bottom display 2732. The first and second delivery tubes 2712 and 2714 are also shown. FIG. 27 also shows a liquid-proof containment vessel 2738 that is used to collect uncured resin and other liquids that may escape from the chamber of the invention during the printing process. The containment vessel 2738 may be used with any example application of the invention.

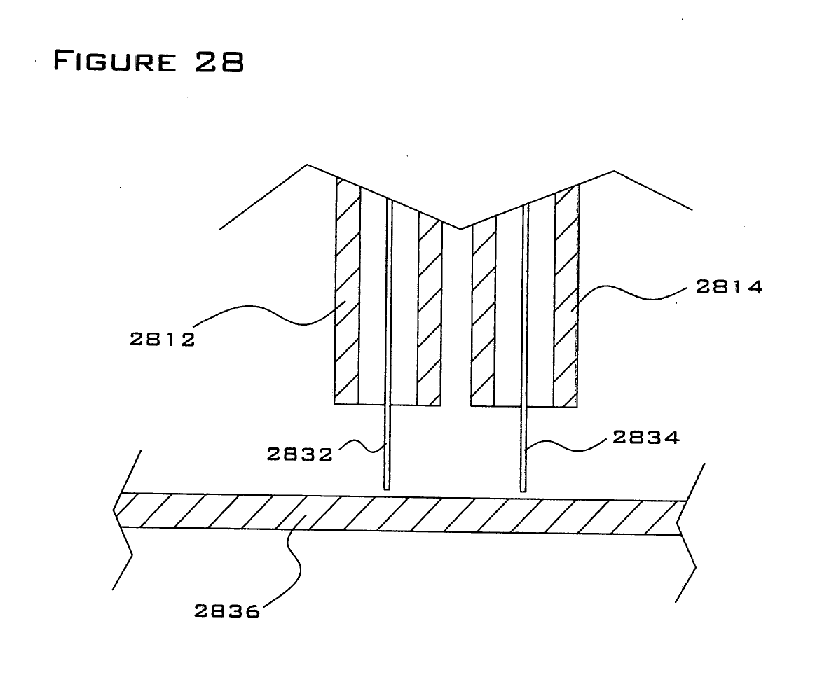

FIG. 28 is a magnified detail cross-section view of the extrusion ends of a first and a second delivery tube (shown previously in FIGS. 13 through 27) showing catheters within the delivery tubes. The first delivery tube 2812 contains a first catheter 2832 within its bore and the second delivery 2814 tube contains a second catheter 2834 within its bore. The first and second catheters 2832 and 2834 may be deployed to deliver raw material such as resin in precise quantities to precise locations on the surface of a display 2836 where emitted electromagnetic radiation from the display 2836 processes the material, such as curing the resins, thereby forming a layer of the printed object. The first and second catheters 2832 and 2834 may also be deployed to remove waste from the internal chamber or to rinse the printed object or the internal chamber. The first and second catheters 2832 and 2834 may also be configured so as to function as remote-controlled, working additive manufacturing emitters of specific wavelengths of electromagnetic radiation, laser light radiation or ultrasound radiation. The positions of the two catheters 2832 and 2834 are adjustable and are set by remote control systems (not shown). The printed object is formed in multiple layers, and as described previously, the positions of the display 2836 and the catheters 2832 and 2834 may be adjusted as required between the printing of each layer of the printed object.

Note that in the above examples, the display surfaces themselves constitute the working surface against which the object is created. The display surface is the surface on which the material sits, and all of the necessary tools for creating the object are situated inside of the display. The size of the working surface is defined by the pixels on the display surface; in other words, the working surface extends from one edge of the display surface to the other. For these reasons, the display-as-print technology described herein represents a significant shift in the paradigm for 3D printing/manufacturing and a departure from the conventional model of a workbench and hand tools.

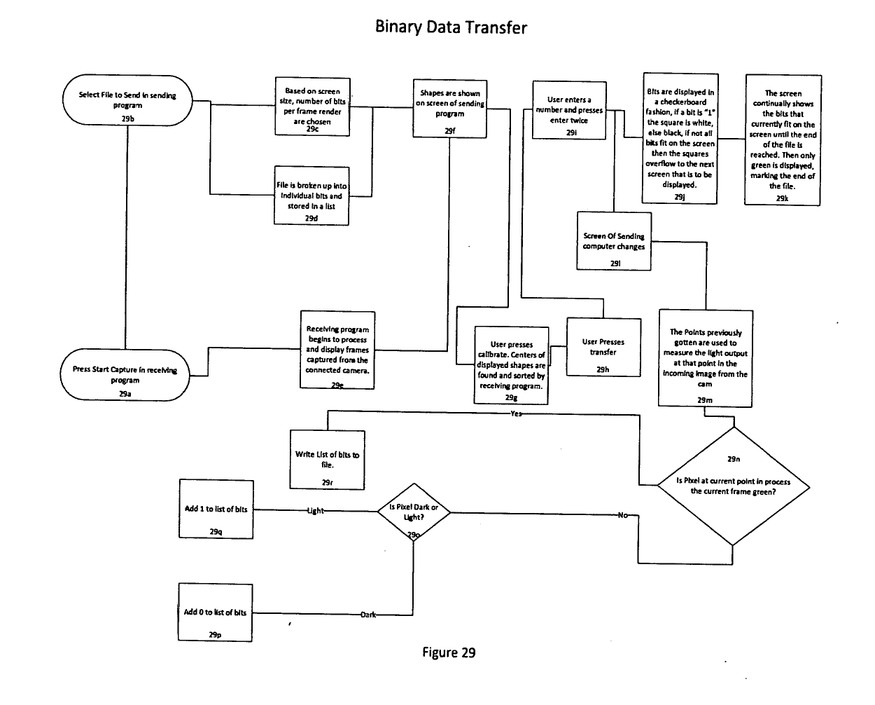

FIGS. 29-31 illustrate one embodiment of the software program and hardware that is used to create an optical network for binary data transfer; note that the minimum optical network requirements set forth herein may be scaled to encompass a global network. The following discussion is an example of providing pixels in a display as a binary output and using a receiving unit to convert those pixels back into relevant data and/or information. In this example, the optical network includes at least two computer monitors (although only one pixel output device is required to display the video output), one camera inputting to a computer running a receiving program, and a sending program that is displayed on a monitor at which the camera is pointed. In a preferred embodiment, the camera sends a video stream in the YCbCr:422 format to the computer running the receiving program utilizing a Blackmagic™ video capture card. As used herein, the term “camera” means any image sensor or image capturing device (for example, any device incorporating a CCD or CMOS sensor) that can output a video stream.

It is important to note that each frame of the incoming video stream is a single-dimensional array of bytes and that the bytes are arranged as Cb, Y1, Cr, Y2, Cb, Y1, Cr, Y2, etc. In the current embodiment of the invention, the formula that is used to convert the video stream from YUV color space to RGB color space assumes that the Y values (which represents the luma component or brightness of the pixel) are in the odd index in the byte array (that is, the incoming frame from the video stream). The formulas (non-proprietary) used for converting from YCbCr color space to the RGB color space are as follows:

int R=Y1+1.402*(Cr−128);

int G=Y1−0.34414*(Cb−128)−0.71414*(Cr−128); and

int B=Y1+1.772*(Cb−128).

In a preferred embodiment, the video stream has a resolution of 4K UHD; if it did not, then the coefficients in the above formulas would change.

As used herein, the term “pixel” has its ordinary meaning in the industry. One definition (provided by whatis.techtarget.com) is “the basic unit of programmable color on a computer display or in a computer image.” As used herein, the term “bit” (short for “binary digit”) has its ordinary meaning in the industry. One definition (again provided by whatis.techtarget.com) is “the smallest unit of data in a computer.” In the context of the present invention, there is one bit per shape, and a shape is comprised of one or more pixels. The exact number of pixels (one or more) that comprise a shape in each application of the invention is defined by parameters that are coded into the software program. As used herein, the term “byte” means a string of bits (in a preferred embodiment, the byte is a numerical value, and the string is comprised of eight bits). As explained more fully below, in the context of the present invention, the bytes contained in the sending program are read into bits by the receiving program.

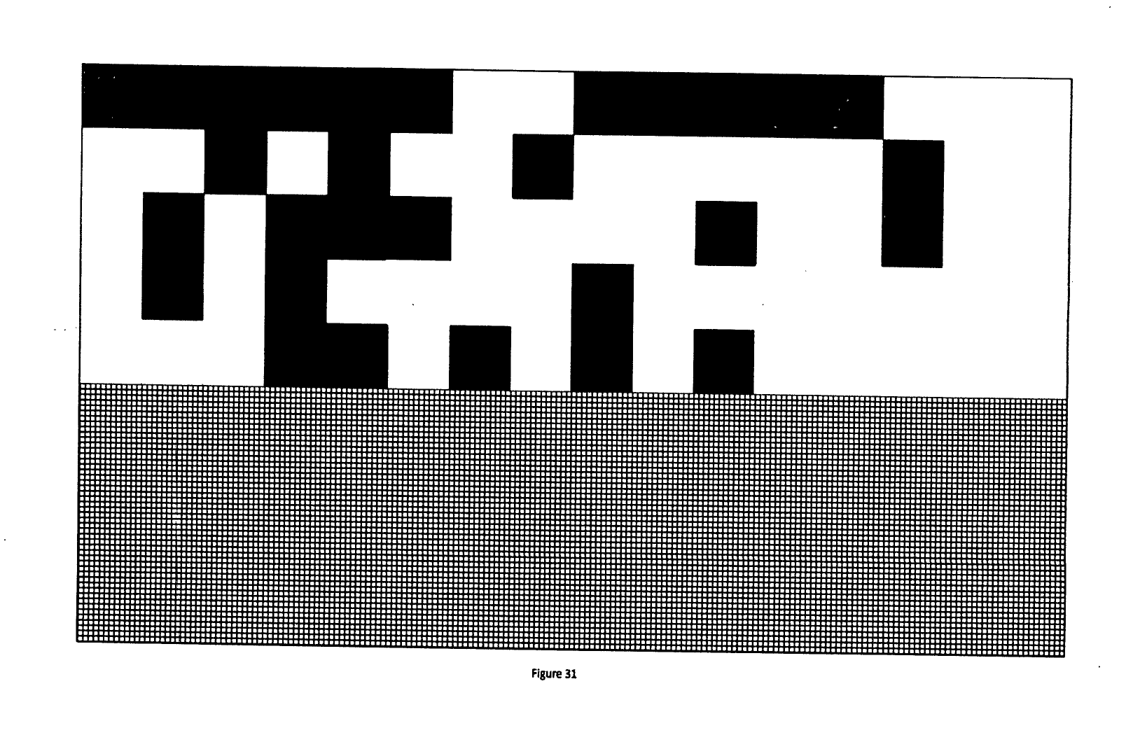

As explained more fully below, in a preferred embodiment of the present invention, a shape is displayed as black, white or green when data is being sent from the sending program to the receiving program and as black or white only during the calibration step (in FIG. 31, the hatching represents the color green). Calibration occurs before a file is sent by the sending program to the receiving program. Prior to calibration, the user selects a file to be processed, and this file is first read into bytes and then into bits. The resulting bits are stored as a list prior to commencement of calibration. The calibration process results in shapes being displayed on a screen so that the receiving program can locate the center of each shape. Once calibration is completed, the shapes are displayed as either black or white, depending on whether the bit that is associated with that shape is a “0” or a “1” (as explained more fully below). Once the system has reached the end of the bit list, the final shape will be displayed as green, signifying to the receiving program that the end of the file has been reached.

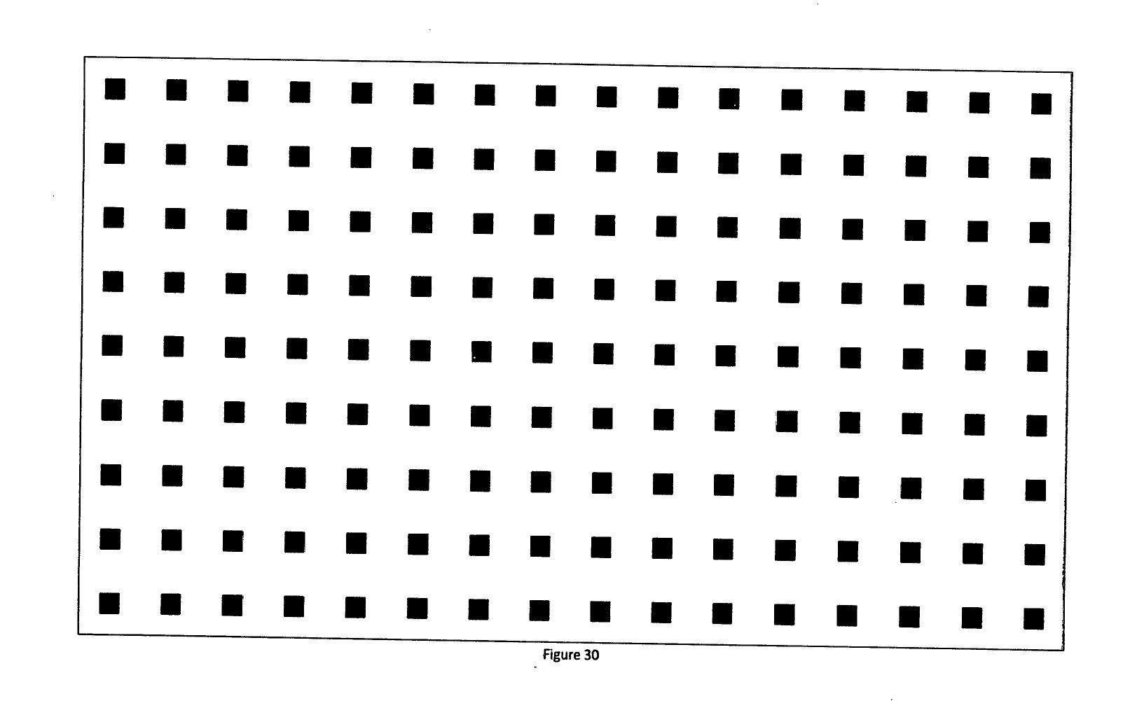

Referring to FIG. 29, at step 29a, the user presses the Start Capture button in the receiving program to begin receiving the video stream. It is assumed that there is an available incoming video stream to the computer running the receiving program. At step 29b, the user selects a file from the sending program. This file could be any type of file, for example, a document, image or program. At step 29c, the sending program determines the size of the screen attached to the monitor of the sending computer. The number of the bits to display is hard-coded in implementation; there is a value for how many bits to display per row and a value for how many rows to display. The size of the bits is calculated by dividing the screen width by the amount of bits per row and the screen height by the amount of rows. At step 29d, the selected file is read by the sending program into a byte array or list. Each of the bytes in this array (or list) is then parsed into individual bits (1's and 0's). Each of these bits is then stored in a separate list, maintaining the order in which the bytes were read. After the selected file is parsed from bytes into bits, and the user selects start capture in the receiving program, the receiving program begins to display frames captured (or received) from the incoming video stream (step 29e). At step 29f, the sending program displays a plurality of black shapes that are completely enclosed in white on the screen displaying output from the sending program (see FIG. 30). The shapes are preferably black and the background is preferably white to provide the greatest amount of contrast available between the shape and the background of the program. (Note that the sending program and the receiving program may be run on the same or different computers, but if they are run on the same computer, then you would need two different monitors to display the receiving program output and the sending program output.) The sending program creates a bounding box around each shape (i.e., there is one bounding box per shape); these bounding boxes will define the squares in the checkerboard pattern discussed below in connection with step 29j (see FIG. 31). The formula (proprietary) for defining the center point and the height and width of the bounding box is as follows:

Width=ScreenWidth/BitsAcross

Height=ScreenHeight/BitsHigh

CenterPointX=ScreenWidth/BitsAcross*ColumnNumber+½*Screen Width/BitsAcross

CenterPointY=ScreenHeight/BitsHigh*RowNumber+½*ScreenHeight/BitsHigh

At step 29f, the center point of the bounding box will correspond to the center point of the shape.

At step 29g, the receiving program starts the calibration process by finding the center of each of the black shapes and ordering (sorting) Cartesian coordinates (points) of the centers first by X then by Y. After the points (as used herein, the term “point” means an X-Y value with no color data associated with it) are sorted, they are stored in a list (referred to below as the “calibration points list”) for later use. In a current embodiment of the invention, the monitor on which the output of the sending program is being displayed is tilted slightly to the right, but less than five (5) degrees from level, assuming that the capturing camera is perfectly level; this positioning of the monitor moves the center of each shape so that the top left is higher in the frame than the top right, which ensures that the receiving program will read the bits from left to right, top to bottom, when converting bits back into bytes.

At step 29gg, each of the coordinates is converted by the receiving program into an array index using the formula Index=(((Center Point Y Value−1)*(Width of Video Frame))+Center Point X Value)*2). The value returned is referred to herein as the “calibration index.” In a preferred embodiment, if the calibration index is divisible by 4, 2 is subtracted from it to ensure that only Y1 values are returned. Because this last step will always return an even number, 1 is added to the calibration index so that each index is a “Y1” in the incoming video frame array.

Once the calibration process is completed, the user presses the transfer button (step 29h), which causes the receiving program to calculate the binary equivalent of what is being displayed by the sending program. Next, the user enters a number (any number) into the terminal on which the sending program is running (step 29i) to signify to the sending program that calibration has been completed. At step 29j, the sending program iterates through the list of bits generated at step 29d and displays a checkerboard-like pattern. (As noted above, the shapes are generated and used to define bounding boxes at step 29f, and the bounding boxes define the squares that comprise the checkerboard pattern that is displayed on the monitor of the sending program.) Each square of the checkerboard is either black or white, black signifying a “0” bit and white signifying a “1” bit. If the file is larger than what can be displayed on a single screen, then multiple frames will be generated and displayed on the same monitor (in the order in which the bits are arranged or listed in the array or list).

At step 29k, the sending program displays the amount of bits that currently fit on the screen until the end of the file is reached. If there is any space left on the screen that is not representing a bit, only green is displayed where that bit would have been represented. At step 29l, the display of the sending program switches from displaying the calibration image to displaying the first frame of bits represented as black or white squares (and the receiving program detects this change). Now that the binary value (according to the receiving program) of the sending program's display is different, the receiving program begins to analyze the incoming video stream and store bits sent by the sending program into a list. At calibration, the receiving program evaluates the equivalent binary value of the calibration screen (that is, the screen on the monitor of the sending program) as if it were already receiving a file, but when the sending program actually starts to display the file, what is displayed on the screen changes. When the binary value is no longer equal to the equivalent binary value generated during calibration (which may or may not occur at the first frame), the receiving program starts storing the new binary values in the list of bits (an empty list is created when the user hits “start capture” and is populated at the current step); it is this list of bits that will be converted into a file (reference step 29r, where bits are converted back into bytes). Note that the receiving program will not override the equivalent binary values if the new (actual) values are the same as the equivalent binary values.

At step 29m, the receiving program uses the calibration indexes previously recorded at step 29gg to analyze the luminance and color at each point in the calibration points list of the current frame on the incoming video stream from the camera pointed at the monitor (reference step 290 below). Note that the invention requires an incoming video stream; however, the invention is agnostic as to the source of the video stream. In one embodiment, the source of the video stream may be a CMOS chip. The display can be any form of hardware that has pixels; although the term “monitor” is used herein, the display is not necessarily a computer monitor. The receiving program must be running on a computer that accepts an incoming video stream. In step 29n, the receiving program iterates through the Y1 values generated at the calibration step for each pixel to determine whether the pixel is green. If yes, then the receiving program proceeds to step 29r; if no, then the receiving program proceeds to step 29o.

At step 29o, the receiving program determines whether a pixel is dark or light adds a “0” to the list of recorded bits if the color is dark (step 29p) and a “1” to the list of recorded bits if the color is light (step 30q). In a preferred embodiment, this is done by determining whether the Y1 value at the index corresponding to the calibration point is greater than or equal to 128 (light) or less than 128 (dark); note that these values may change in other embodiments of the invention. If the color of a pixel at a given point in the calibration point list is green, then the end of the file has been reached, and no bit is added to the list of bits. When the receiving program reaches a green pixel, the list of bits is converted to a list of bytes, which is then written to a file called file.bin (step 29r).

At this point, the user has used light as a network medium for transferring data. This can be any amount of data (assuming basic hardware requirements are met, such as RAM capacity) and any kind of data. This process converts pixels into bits, then converts those bits into bytes. Once those bytes have been written to a file, the receiving computer will have the full binary file that was sent by the sending program. Multiple receiving programs could utilize a single monitor to achieve true multicast.

For ease of reference:
Reference numbers 1310 and 1410 refer to the same item.
Reference numbers 1312, 1412, 1512, 1612, 1712, 1812, 1912, 2012, 2112, 2212, 2312, 2412, 2512, 2612, 2712 and 2812 refer to the same item.
Reference numbers 1314, 414, 1514, 1614, 1714, 1814, 1914, 2014, 2114, 2214, 2314, 2514, 2614, 2714, and 2814 refer to the same item.
Reference numbers 1316, 1416, 1516 and 1616 refer to the same item.
Reference numbers 1318, 1418, 1518 and 1618 refer to the same item.
Reference numbers 1320 and 1520 refer to the same item.
Reference numbers 1322, 1422, 1522 and 1622 refer to the same item.
Reference numbers 1324, 1424, 1524 and 1624 refer to the same item.
Reference numbers 1326, 1426, 1626 refer to the same item.
Reference numbers 1511 and 1611 refer to the same item.
Reference numbers 1710 and 1810 refer to the same item.
Reference numbers 1716 and 1816 refer to the same item.
Reference numbers 1718 and 1818 refer to the same item.
Reference numbers 1720 and 1920 refer to the same item.
Reference numbers 1722 and 1922 refer to the same item.
Reference numbers 1724 and 1924 refer to the same item.
Reference numbers 1726 and 1926 refer to the same item.
Reference numbers 1736, 1836, and 1936 refer to the same item.
Reference numbers 1738, 1838, and 1938 refer to the same item.
Reference numbers 1740, 1840, and 1940 refer to the same item.
Reference numbers 1742, 1842, and 1942 refer to the same item.
Reference numbers 1744 and 1844 refer to the same item.
Reference numbers 1746 and 1846 refer to the same item.
Reference numbers 1748 and 1848 refer to the same item.
Reference numbers 1750 and 1850 refer to the same item.
Reference numbers 2010 and 2110 refer to the same item.
Reference numbers 2016, 2116 and 2216 refer to the same item.
Reference numbers 2018, 2118 and 2218 refer to the same item.
Reference numbers 2020, 2120 and 2220 refer to the same item.
Reference numbers 2022, 2122 and 2222 refer to the same item.
Reference numbers 2024 and 2124 refer to the same item.
Reference numbers 2026 and 2126 refer to the same item.
Reference numbers 2028 and 2128 refer to the same item.
Reference numbers 2030 and 2130 refer to the same item.
Reference numbers 2040 and 2140 refer to the same item.
Reference numbers 2048, 2148 and 2248 refer to the same item.
Reference numbers 2050 and 2250 refer to the same item.
Reference numbers 2152 and 2252 refer to the same item.
Reference numbers 2154 and 2254 refer to the same item.
Reference numbers 2156 and 2256 refer to the same item.
Reference numbers 2310 and 2410 refer to the same item.
Reference numbers 2316, 2416 and 2516 refer to the same item.
Reference numbers 2318, 2418 and 2518 refer to the same item.
Reference numbers 2320, 2420 and 2520 refer to the same item.
Reference numbers 2436 and 2536 refer to the same item.
Reference numbers 2438 and 2538 refer to the same item.
Reference numbers 2440 and 2540 refer to the same item.
Reference numbers 2442 and 2542 refer to the same item.
Reference numbers 2444 and 2544 refer to the same item.
Reference numbers 2446 and 2546 refer to the same item.
Reference numbers 2448 and 2548 refer to the same item.
Reference numbers 2450 and 2550 refer to the same item.
Reference numbers 2452 and 2552 refer to the same item.
Reference numbers 2454 and 2554 refer to the same item.
Reference numbers 2456 and 2556 refer to the same item.
Reference numbers 2458 and 2558 refer to the same item.
Reference numbers 2616 and 2716 refer to the same item.
Reference numbers 2618 and 2718 refer to the same item.
Reference numbers 2620 and 2720 refer to the same item.
Reference numbers 2622 and 2722 refer to the same item.
Reference numbers 2624 and 2724 refer to the same item.
Reference numbers 2626 and 2726 refer to the same item.
Reference numbers 2628 and 2728 refer to the same item.
Reference numbers 2630 and 2730 refer to the same item.
Reference numbers 2632 and 2732 refer to the same item.

The following patents and publications are incorporated by reference in their entireties: U.S. Pat. Nos. 3,227,553; 4,330,615; 6,348,302; 7,085,490; and U.S. Publications 2002/0102475; 2010/0061897; 2015/0187265; 2015/0187987; and 2015/0188095.

Although the invention has been described above in terms of specific embodiments, it is to be understood that the invention is not limited to these disclosed embodiments. Upon reading the teachings of this disclosure many modifications and other embodiments of the invention will come to mind of those skilled in the art to which this invention pertains, and which are intended to be and are covered by both this disclosure and the appended claims. It is intended that the scope of the invention should be determined by proper interpretation and construction of the appended claims and their legal equivalents, as understood by those of skill in the art relying upon the disclosure in this specification and the attached drawings.

As used in the claims, the references to “specific wavelengths” may be the same or different wavelengths. As used in the claims, the term “building material” means any material (for example, but not limited to, plastic) from which a three-dimensional object can be constructed. The building material may be, but is not required to be, in the form of an uncured resin. In an alternate embodiment of the present invention, the building material is a biological material. As used in the claims, the term “process” means to change from one physical state to another, as in, for example, curing, rupturing, sintering and melting; provided, however, that the term “process” is not limited to these particular methods but covers any method of synthesizing a three-dimensional object.

1. A method for creating a two-dimensional image comprising the steps of:
providing a substrate with a first layer of microencapsulated material, the microencapsulated material being photosensitive;
providing a substrate with a second layer of microencapsulated material, the microencapsulated material being electrically conductive;
exposing the first layer of microencapsulated material to a first specific wavelength of radiation in a specific image pattern, thereby releasing the photosensitive material from microencapsulation;
exposing the released photosensitive material to a second specific wavelength to process the photosensitive material and bond it to a first surface of the substrate;
exposing the second layer of microencapsulated material to a third specific wavelength of radiation in a specific image pattern, thereby releasing the electrically conductive material from microencapsulation; and
exposing the released electrically conductive material to a fourth specific wavelength of radiation to process the electrically conductive material and bond it to a second surface of the substrate.

2. A method for creating a two-dimensional image comprising the steps of:
providing a substrate with a layer of microencapsulated material, the microencapsulated material being photosensitive;
exposing the layer microencapsulated material to a first specific wavelength of radiation in a specific image pattern, thereby releasing the photosensitive material from microencapsulation; and
exposing the released photosensitive material to a second specific wavelength to process the photosensitive materials and bond it to a surface of the substrate.

3. A method for depositing electrically conductive materials onto a substrate comprising the steps of:
providing a substrate with a layer of microencapsulated material, the microencapsulated material being at least partially photosensitive and at least partially electrically conductive;
exposing the layer of microencapsulated material to a first specific wavelength of radiation in a specific pattern, thereby releasing the electrically conductive material from microencapsulation; and
exposing the released electrically conductive material to a second specific wavelength of radiation to process the electrically conductive material and bond it to a surface of the substrate.

4. A method for generating an electrically conductive three-dimensional object comprising the steps of:
depositing onto a surface a microencapsulated material that is at least partially comprised of photosensitive material and at least partially comprised of electrically conductive material in powder, slurry or liquid form;
exposing the microencapsulated material to a first specific wavelength of radiation, thereby releasing the electrically conductive material from microencapsulation;
exposing the released electrically conductive material to a second specific wavelength of radiation to process the electrically conductive material to form a first object layer;
depositing onto the first object layer a microencapsulated material that is at least partially comprised of photosensitive material and at least partially comprised of electrically conductive material in powder, slurry or liquid form;
exposing the microencapsulated material that is deposited onto the first object layer to a third specific wavelength of radiation, thereby releasing the microencapsulated electrically conductive material from microencapsulation;
exposing the released electrically conductive material that is deposited onto the first object layer to a fourth specific wavelength of radiation to process the electrically conductive material to form a second object layer; and
repeating the deposition and exposure steps to create as many layers as are necessary to complete the object.

5. A method for generating an electrically conductive three-dimensional object comprising the steps of:
depositing onto a surface a microencapsulated material that is comprised at least partially of photosensitive material and at least partially of electrically conductive material in powder, slurry or liquid form;
exposing the microencapsulated material to a first specific wavelength of radiation, thereby releasing the electrically conductive material from microencapsulation;
exposing the released electrically conductive material to a second specific wavelength of radiation to process the electrically conductive material and bond it to the surface to form a first additive layer;
depositing onto the first additive layer a microencapsulated material that is comprised at least partially of photosensitive material and at least partially of electrically conductive material in powder, slurry or liquid form;
exposing the microencapsulated material that is deposited onto the first additive layer to a third specific wavelength of radiation, thereby releasing the microencapsulated electrically conductive material from microencapsulation;
exposing the released electrically conductive material that is deposited onto the first additive layer to a fourth specific wavelength of radiation to process the electrically conductive material to form a second additive layer; and
repeating the deposition and exposure steps to create as many layers as are necessary to complete the object.

6. A method for generating a three-dimensional object comprising the steps of:
depositing onto a surface a microencapsulated material that is comprised at least partially of photosensitive material and at least partially of building material in powder, slurry or liquid form;
exposing the microencapsulated material to a first specific wavelength of radiation, thereby releasing the building material from microencapsulation;
exposing the released building material to a second specific wavelength of radiation to process the building material to form a first object layer;
depositing onto the first object layer a microencapsulated material that is comprised at least partially of photosensitive material and at least partially of building material in powder, slurry or liquid form;
exposing the microencapsulated material that is deposited onto the first object layer to a third specific wavelength of radiation, thereby releasing the microencapsulated building material from microencapsulation;
exposing the released building material that is deposited onto the first object layer to a fourth specific wavelength of radiation to process the building material to form a second object layer; and
repeating the deposition and exposure steps to create as many layers as are necessary to complete the object.

7. A method for generating a three-dimensional object comprising the steps of:
depositing onto a surface a microencapsulated material that is comprised at last partially of photosensitive material and at least partially of building material in powder, slurry or liquid form;
exposing the microencapsulated material to a first specific wavelength of radiation, thereby releasing the building material from microencapsulation;
exposing the released building material to a second specific wavelength of radiation to process the building material and bond it to the surface to form a first additive layer;
depositing onto the first additive layer a microencapsulated material that is comprised at least partially of photosensitive material and at least partially of building material in powder, slurry or liquid form;
exposing the microencapsulated material that is deposited onto the first additive layer to a third specific wavelength of radiation, thereby releasing the microencapsulated building material from microencapsulation;
exposing the released building material that is deposited onto the first additive layer to a fourth specific wavelength of radiation to process the building material to form a second additive layer; and
repeating the deposition and exposure steps to create as many layers as are necessary to complete the object.

8. The method of any of claims 1-7, wherein the step of exposing the microencapsulated material to a specific wavelength is implemented via at least one display device that is in direct contact with the microencapsulated material, and the step of exposing the released material to a specific wavelength is implemented via at least one display device that is in direct contact with the released material.

9. The method of claim 8, wherein the at least one display device is moveable.

10. The method of any of claims 4-7, wherein the step of exposing the microencapsulated material to a specific wavelength is implemented via at least one display device that is in direct contact with the microencapsulated material, and the step of exposing the released material to a specific wavelength is implemented via at least one display device that is in direct contact with the released material, and wherein the at least one display device is configured to move away from the object as it increases in size.

11. The method of any of claims 4-7, wherein the step of exposing the microencapsulated material to a specific wavelength and the step of exposing the released material to a specific wavelength are implemented by more than one display device, and wherein the more than one display devices are configured to form a manufacturing chamber within which the object is generated.

12. The method of any of claims 4-7, wherein each of the more than one display devices has a display surface that is load-bearing and configured to provide a surface against which the object rests as it is being generated.

13. The method of any of claims 1-7, wherein the step of exposing the microencapsulated material to a specific wavelength is implemented via at least one catheter that is in direct contact with the microencapsulated material, and the step of exposing the released material to a specific wavelength is implemented via at least one catheter that is in direct contact with the released material.

14. The method of claim 13, wherein the at least one catheter is moveable.

15. The method of any of claims 4-7, wherein the step of exposing the microencapsulated material to a specific wavelength is implemented via at least one catheter that is in direct contact with the microencapsulated material, and the step of exposing the released material to a specific wavelength is implemented via at least one catheter that is in direct contact with the released material, and wherein the at least one catheter is configured to move away from the object as it increases in size.

16. A method for generating a three-dimensional object comprising the steps of:
depositing onto a surface building material that is in powder, slurry or liquid form, wherein the building material is comprised at least in part of a photosensitive material;
exposing the building material to a first specific wavelength of radiation to process the building material to form a first object layer;
depositing onto the first object layer additional building material in powder, slurry or liquid form, wherein the building material is comprised at least in part of a photosensitive material;
exposing the additional building material that is deposited onto the first object layer to a second specific wavelength of radiation to process the additional building material to form a second object layer; and
repeating the deposition and exposure steps to create as many layers as are necessary to complete the object.

17. A method for generating a three-dimensional object comprising the steps of:
depositing onto a surface building material in powder, slurry or liquid form, wherein the building material is comprised at least in part of a photosensitive material;
exposing the building material to a first specific wavelength of radiation to process the building material and bond it to the surface to form a first additive layer;
depositing onto the first additive layer additional building material in powder, slurry or liquid form, wherein the building material is comprised at least in part of a photosensitive material;
exposing the additional building material that is deposited onto the first additive layer to a second specific wavelength of radiation to process the additional building material to form a second additive layer; and
repeating the deposition and exposure steps to create as many layers as are necessary to complete the object.

18. A method for generating a three-dimensional object comprising the steps of:
providing building material that is in powder, slurry or liquid form, wherein the building material is comprised at least in part of a photosensitive material;
exposing a first portion of the building material to a first specific wavelength of radiation to process the first portion of the building material to form a first object layer;
exposing a second portion of the building material to a second specific wavelength of radiation to process the building material to form a second object layer; and
repeating the exposure steps to create as many layers as are necessary to complete the object.

19. The method of any of claims 16-18, wherein the step of exposing the building material to a specific wavelength is implemented via at least one display device that is in direct contact with the building material, and the step of exposing the additional building material to a specific wavelength is implemented via at least one display device that is in direct contact with the additional building material.

20. The method of claim 19, wherein the at least one display device is moveable.

21. The method of any of claims 16-18, wherein the step of exposing the building material to a specific wavelength is implemented via at least one display device that is in direct contact with the building material, and the step of exposing the additional building material to a specific wavelength is implemented via at least one display device that is in direct contact with the additional building material, and wherein the at least one display device is configured to move away from the object as it increases in size.

22. The method of any of claims 16-18, wherein the step of exposing the building material to a specific wavelength and the step of exposing the additional building material to a specific wavelength are implemented via more than one display device that is in direct contact with the additional building material, and wherein the more than one display devices are configured to form a manufacturing chamber within which the object is generated.

23. The method of any of claims 16-18, wherein each of the more than one display devices has a display surface that is load-bearing and configured to provide a surface against which the object rests as it is being generated.

24. The method of any of claims 16-18, wherein the step of exposing the building material to a specific wavelength is implemented via at least one catheter that is in direct contact with the building material, and the step of exposing the additional building material to a specific wavelength is implemented via at least one catheter that is in direct contact with the additional building material.

25. The method of claim 24, wherein the at least one catheter is moveable.

26. The method of any of claims 16-18, wherein the step of exposing the building material to a specific wavelength is implemented via at least one catheter that is in direct contact with the building material, and the step of exposing the additional building material to a specific wavelength is implemented via at least one catheter that is in direct contact with the additional building material, and wherein the at least one catheter is configured to move away from the object as it increases in size.

27. The method of any of claim 1-7 or 16-18, wherein at least one of the exposure steps involves radiation in the range of 10 nanometers to one meter.

28. The method of any of claim 1-7 or 16-18, wherein at least one of the exposure steps is performed by a laser.

29. The method of any of claim 1-7 or 16-18, wherein the radiation is controllable on a pixel-by-pixel level.

30. A computer-implemented system for generating a two-dimensional image, the system comprising:
(a) at least one pixel output device;
(b) a camera inputting to a computer on which is running a receiving program;
(c) a sending program that is displayed on the at least one pixel output device and at which the camera is pointed;
wherein when a file is selected from the sending program, the sending program reads the file into bytes, parses the bytes into bits, and saves the bits to a first bit list;
wherein the sending program displays a plurality of shapes in a checkerboard pattern, each shape comprising one or more pixels, the checkerboard pattern being determined by the first bit list, and the number of pixels that comprise a shape being defined by pre-coded parameters;
wherein the camera sends a video stream of the checkerboard pattern to the computer that is running the receiving program;
wherein the camera is any image sensor or image capturing device; and
wherein the receiving program analyzes pixels in the frames from the incoming video stream for luminance and color, converts the pixels into a bit list, converts the bit list into a byte list, and writes the byte list to a file.

31. A computer-implemented method of generating a two-dimensional image comprising the steps of:
(a) selecting a file and using a sending program to read the file into a first set of bytes and to convert the first set of bytes into a first set of bits;
(b) displaying on a display one or more pixels as determined by the first set of bits;
(c) using an image sensor or image capturing device to create a video stream of the image that is displayed on the display;
(d) capturing the video stream with the receiving program; and
(e) using the receiving program to convert pixels in the video stream into a second set of bits, to convert the second set of bits into a second set of bytes, and to write the second set of bytes to a file.
